(19) United States
(12) Patent Application Publication
(10) Pub. No.: US 2015/0221798 A1
(43) Pub. Date: Aug. 6, 2015

(54) SOLAR CELL MODULE AND PHOTOVOLTAIC APPARATUS

(71) Applicant: SHARP KABUSHIKI KAISHA, Osaka (JP)

(72) Inventors: Seiji Ohhashi, Osaka-shi (JP); Hideki Uchida, Osaka-shi (JP); Yasuyuki Umenaka, Osaka-shi (JP)

(21) Appl. No.: 14/430,679

(22) PCT Filed: Sep. 18, 2013
(86) PCT No.: PCT/JP2013/075095

§ 371 Date: Mar. 24, 2015

(30) Foreign Application Priority Data
Sep. 25, 2012 (JP) 2012-211020

(51) Int. Cl. H01L 31/055

(52) U.S. Cl. CPC H01L 31/055

(57) ABSTRACT

Provided is a solar cell module capable of increasing module output and a photovoltaic apparatus. A light-guiding body which has a light incidence surface and a light-emitting surface having an area smaller than that of the light incidence surface and converts exterior light incident from the light incidence surface into fluorescent light by a phosphor to emit from the light-emitting surface and N (N is an integer of 4 or more) solar cells of a same type which receive the fluorescent light emitted from the light-emitting surface of the light-guiding body are included, the N solar cells are connected in parallel in a plurality of pieces to thereby form L (L is an integer of 2 or more) parallel-connection blocks each of which has the plurality of solar cells mutually connected in parallel, and the L parallel-connection blocks are mutually serially connected.

### TECHNICAL FIELD

The present invention relates to a solar cell module and a photovoltaic apparatus.

### BACKGROUND ART

As a solar cell module that has a solar cell (solar cell element) installed on an end surface of a light-guiding body (light-condensing body) and makes light propagating inside the light-guiding body incident on the solar cell to perform power generation, a solar cell module described in PTL 1 is known. The solar cell module in PTL 1 causes a phosphor to emit light by sunlight incident inside the light-guiding body for light-condensing on the solar cell installed on the end surface of the light-guiding body.

### CITATION LIST

### Patent Literature

PTL 1: Japanese Unexamined Patent Application Publication No. 58-49860

### SUMMARY OF INVENTION

### Technical Problem

In such a solar cell module of a light-condensing type, when a size of the light-guiding body becomes large, light condensed on the end surface of the light-guiding body is not able to be received with only one solar cell. Therefore, it becomes necessary to install a plurality of solar cells on the end surface of the light-guiding body and connect them electrically, but, depending on a way of connecting the plurality of solar cells, module output is greatly reduced, thus causing an undesirable result in some cases.

An object of the present invention is to provide a solar cell module capable of increasing module output and a photovoltaic apparatus.

### Solution to Problem

A solar cell module of a first aspect of the present invention includes: a light-guiding body which has a light incidence surface and a light-emitting surface having an area smaller than that of the light incidence surface and converts exterior light incident from the light incidence surface into fluorescent light by a phosphor to emit from the light-emitting surface; and N (N is an integer of 4 or more) solar cells of a same type which receive the fluorescent light emitted from the light-emitting surface of the light-guiding body, wherein the N solar cells are connected in parallel in a plurality of pieces to thereby form L (L is an integer of 2 or more) parallel-connection blocks each of which has the plurality of solar cells mutually connected in parallel, and the L parallel-connection blocks are mutually serially connected.

When each short circuit current of the N solar cells in the case of making the exterior light incident on the entire light incidence surface uniformly is Iⱼ (j is an integer from 1 to N), a sum of short circuit currents of the plurality of solar cells included in each parallel-connection block of the L parallel-connection blocks is ITᵢ (i is an integer from 1 to L), a difference, among arbitrary two of the parallel-connection blocks selected from the L parallel-connection blocks, between the ITᵢs of the two parallel-connection blocks that have a greatest difference between the ITᵢs is ID₁, and a difference, among arbitrary two of the solar cells selected from the N solar cells, between the Iⱼs of the two solar cells that have a greatest difference between the Iⱼs is ID₂, the ID₁ and the ID₂ may satisfy a relational expression of ID₁<ID₂.

The light-guiding body may be a plate-shaped body having one or more side, the N solar cells may be arranged side by side along one side of the light-guiding body, and a solar cell that is arranged at one end portion in an arrangement direction of the N solar cells and a solar cell that is arranged at the other end portion in the arrangement direction of the N solar cells may be included in the parallel-connection blocks which are different from each other.

A solar cell module of a second aspect of the present invention includes: a light-guiding body which has a light incidence surface and a light-emitting surface having an area smaller than that of the light incidence surface and converts exterior light incident from the light incidence surface into fluorescent light by a phosphor to emit from the light-emitting surface; and N (N is an integer of 3 or more) solar cells of a same type which receive the fluorescent light emitted from the light-emitting surface of the light-guiding body, wherein M (M is an integer larger than 1 and smaller than N) solar cells of the N solar cells are connected in parallel in a plurality of pieces to thereby form L (L is an integer of 1 or more) parallel-connection blocks each of which has a plurality of solar cells mutually connected in parallel and (N-M) solar cell which is not included in the L parallel-connection block, and the L parallel-connection blocks and the (N-M) solar cell are mutually serially connected.

When each short circuit current of the N solar cells in the case of making the exterior light incident on the entire light incidence surface uniformly is Iⱼ (j is an integer from 1 to N), a solar cell having a minimum Iⱼ may be included in any of the L parallel-connection blocks.

When each short circuit current of the N solar cells in the case of making the exterior light incident on the entire light incidence surface uniformly is Iⱼ (j is an integer from 1 to N), a sum of short circuit currents of the plurality of solar cells included in each parallel-connection block of the L parallel-connection blocks is ITᵢ (i is an integer from 1 to L), a difference, among arbitrary two of the parallel-connection blocks selected from the L parallel-connection blocks, between the ITᵢs of the two parallel-connection blocks that have a greatest difference between the ITᵢs is ID₁, a difference, among arbitrary two of the solar cells selected from the N solar cells, between the Iⱼs of the two solar cells that have a greatest difference between the Iⱼs is ID₂, and a difference, among arbitrary one of the parallel-connection block selected from the L parallel-connection blocks and arbitrary one of the solar cell selected from the (N-M) solar cell, between the ITᵢ and the Iⱼ of the one parallel-connection block and the one solar cell that have a greatest difference between the ITᵢ and the Iⱼ is ID₃, the ID₁, the ID₂ and the ID₃ may satisfy relational expressions of ID₁<ID₂ and ID₃<ID₂.

The light-guiding body may be a plate-shaped body having one or more side, the N solar cells may be arranged side by side along one side of the light-guiding body, and at least one of a solar cell that is arranged at one end portion in an arrangement direction of the N solar cells and a solar cell that is arranged at the other end portion in the arrangement direction of the N solar cells may be included in any of the L parallel-connection blocks.

A solar cell module of a third aspect of the present invention includes: a light-guiding body which has a light incidence surface and a light-emitting surface having an area smaller than that of the light incidence surface and converts exterior light incident from the light incidence surface into fluorescent light by a phosphor to emit from the light-emitting surface; and N (N is an integer of 3 or more) solar cells which receive the fluorescent light emitted from the light-emitting surface of the light-guiding body, wherein the light-guiding body is a plate-shaped body having one or more side, the N solar cells are arranged side by side along one side of the light-guiding body and constituted by being mutually serially connected, and light-receiving areas of the solar cells are increased sequentially as being close to both end portions from a center portion in an arrangement direction of the N solar cells.

The light-receiving areas of the solar cells may be increased sequentially as being close to both end portions from the center portion in the arrangement direction of the N solar cells such that each short circuit current of the N solar cells in the case of making the exterior light incident on the entire light incidence surface uniformly is equal.

The light-receiving areas of the N solar cells may vary in accordance with a length of each of the solar cells.

A photovoltaic apparatus of the present invention is provided with the solar cell module of the present invention.

### Advantageous Effects of Invention

According to the present invention, it is possible to provide a solar cell module capable of increasing module output and a photovoltaic apparatus.

### BRIEF DESCRIPTION OF DRAWINGS

FIG. 1 is an exploded perspective view showing a schematic structure of a solar cell module.

FIG. 2 is a sectional view of the solar cell module shown in FIG. 1.

FIG. 3 is a view for explaining an electrical connection relation of solar cells in a first embodiment.

FIG. 4 is a graph showing results that a light intensity at a light-emitting surface of a light-guiding body is obtained by simulation.

FIG. 5 is a graph showing results that dependency of an open circuit voltage with respect to the light intensity is measured.

FIG. 6 is a graph showing results that maximum output of solar cells when irradiance is changed is measured.

FIG. 7 is a partial perspective view of a solar cell element group in the first embodiment.

FIG. 8 is an exploded perspective view of the solar cell element group in the first embodiment.

FIG. 9 is a view for explaining an electrical connection relation of other solar cells in the first embodiment.

FIG. 10 is a view for explaining an electrical connection relation of solar cells in a second embodiment.

FIG. 11 is a view for explaining an electrical connection relation of other solar cells in the second embodiment.

FIG. 12 is a view for explaining an electrical connection relation of solar cells in a third embodiment.

FIG. 13 is a partial perspective view of a solar cell element group in the third embodiment.

FIG. 14 is an exploded perspective view of the solar cell element group in the third embodiment.

FIG. 15 is a view for explaining an electrical connection relation of other solar cells in the third embodiment.

FIG. 16 is a view for explaining a solar cell in a fourth embodiment.

FIG. 17 is a schematic structural view of a photovoltaic apparatus.

### DESCRIPTION OF EMBODIMENTS

### [Solar Cell Module]

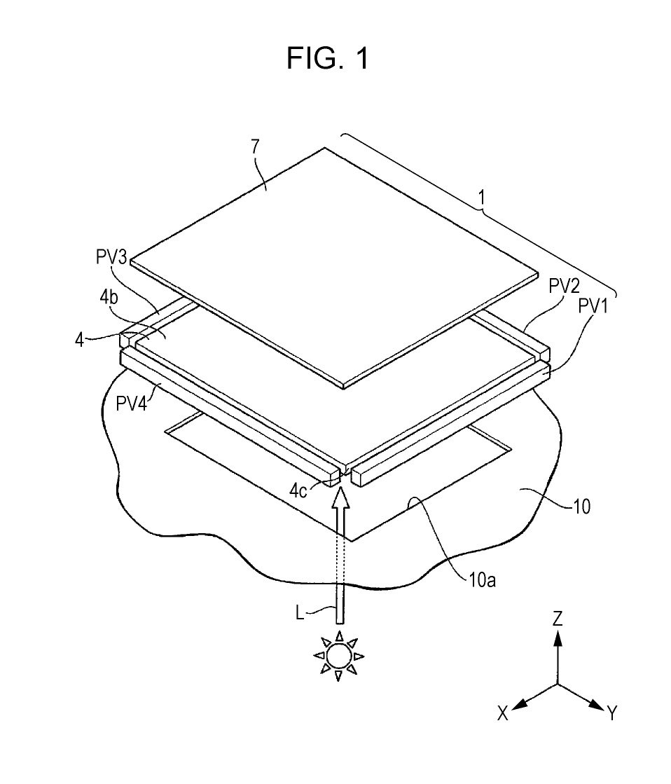

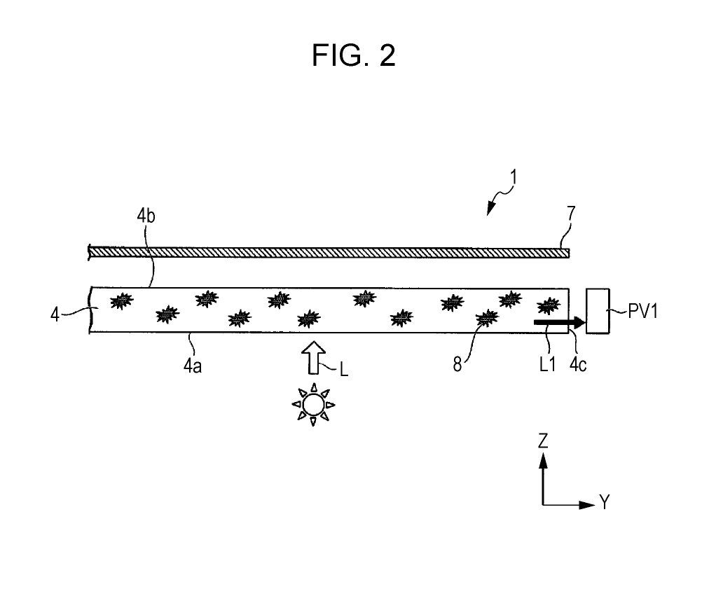

First, description will be given for a schematic structure of a solar cell module 1 shown in FIG. 1 and FIG. 2 with reference to FIG. 1 and FIG. 2.

Note that, FIG. 1 is a perspective view showing one specific example of the solar cell module 1 and FIG. 2 is a sectional view of the solar cell module 1 shown in FIG. 1.

The solar cell module 1 is provided with a plurality of solar cell element groups PV1, PV2, PV3 and PV4 which convert light (sunlight) L into electricity, a light-guiding body (light-condensing body) 4 which guides (condenses) the received sunlight L to the solar cell element groups PV1, PV2, PV3 and PV4, and a frame body 10 which holds these solar cell element groups PV1, PV2, PV3 and PV4 and the light-guiding body 4 integrally.

The light-guiding body 4 is composed of a substantially rectangular plate-shaped member which is provided with a first main surface 4a serving as a light incidence surface, a second main surface 4b opposing to the first main surface 4a, and a first end surface 4c serving as a light-emitting surface. Note that, in FIG. 1 and FIG. 2, the first main surface 4a and the second main surface 4b are arranged in parallel to an XY plane (perpendicular to a Z axis).

For the light-guiding body 4, for example, one that an optical functional material is dispersed inside a base material (transparent substrate) composed of an organic material or an inorganic material having high transparency such as an acrylic resin, a polycarbonate resin, or glass is usable.

As the optical functional material, for example, a phosphor 8 which absorbs ultraviolet light or visible light and radiates visible light or infrared light is usable. Light L1 radiated from the phosphor 8 is propagated inside the light-guiding body 4 to be emitted from the first end surface 4c, and used for power generation in the solar cell element groups PV1, PV2, PV3 and PV4. Note that, the visible light is light having a wavelength region of 380 nm to 750 nm, the ultraviolet light is light having a wavelength region less than 380 nm, and the infrared light is light having a wavelength region more than 750 nm.

Moreover, in the light-guiding body 4, a reflection layer 7 which is in contact with the second main surface 4b via an air layer or directly with the second main surface 4b without the air layer is disposed. This reflection layer 7 reflects the light L1 which travels from an inside of the light-guiding body 4 toward an outside of the light-guiding body 4 (light radiated from the phosphor 8) or light L which is incident from the first main surface 4a and emitted from the second main surface 4b without being absorbed in the optical functional material toward the inside of the light-guiding body 4.

As the reflection layer 7, a reflection layer composed of a metal film made of silver, aluminum or the like, a reflection layer composed of a dielectric multilayer film such as ESR (Enhanced Specular Reflector) reflective film (made by 3M Company) or the like is usable. The reflection layer 7 may be a mirror reflection layer by which incident light is mirror-reflected or may be a scattering reflection layer by which incident light is scatteringly reflected. In a case where the scattering reflection layer is used for the reflection layer 7, a light amount of light which advances directly in directions of the solar cell element groups PV1, PV2, PV3 and PV4 increases, so that light-condensing efficiency into the solar cell element groups PV1, PV2, PV3 and PV4 is improved and a power generation amount increases. Moreover, since reflecting light is scattered, change in the power generation amount due to time or seasons is averaged. Note that, as the scattering reflection layer, micro-foamed PET (polyethylene terephthalate) (made by Furukawa Electric Co., Ltd.) or the like is usable.

Then, this light-guiding body 4 absorbs a part of the light L which is incident from the light incidence surface 4a by the phosphor 8, and condenses the light L1 which is radiated from this phosphor 8 into the light-emitting surface 4c having an area smaller than that of the light incidence surface 4a to emit outward.

The solar cell element groups PV1, PV2, PV3 and PV4 are arranged so as to have light-receiving surfaces opposed to the first end surfaces 4c of the light-guiding body 4. Moreover, the solar cell element groups PV1, PV2, PV3 and PV4 are composed by further electrically connecting a plurality of solar cells (not shown in FIG. 1).

For these solar cells, for example, a publicly known solar cell such as a silicon solar cell, a compound solar cell or an organic solar cell is able to be used. Among them, the compound solar cell which uses a compound semiconductor is capable of high-efficient power generation and thus preferably used for the solar cell element groups PV1, PV2, PV3 and PV4. In addition, it is preferable that the solar cell element groups PV1, PV2, PV3 and PV4 (solar cells) are optically adhered to the first end surface 4c.

Note that, in the solar cell module 1 shown in FIG. 1, a structure in which the plurality (four) of solar cell element groups PV1, PV2, PV3 and PV4 (solar cells) are installed on all (four) of the first end surfaces 4c of the light-guiding body 4 is exemplified, but there is no limitation to such a structure. For example, there may be a structure in which the solar cell element groups (solar cells) are installed on a part (one side, two sides or three sides) of the first end surfaces 4c of the light-guiding body 4.

Furthermore, in a case where the solar cell element group (solar cell) is installed on a part of the end surfaces of the light-guiding body 4, it is preferable to install a reflection layer on the first end surface 4c on which the solar cell element group (solar cell) is not installed. This reflection layer is provided on the first end surface 4c via an air layer or so as to be directly in contact with the first end surface 4c without the air layer. Then, this reflection layer reflects light which travels from the inside of the light-guiding body 4 toward the outside of the light-guiding body 4 (light radiated from the phosphor) toward the inside of the light-guiding body 4. Note that, for this reflection layer, one made of a material same as that of the above reflection layer 7 is usable.

The frame body 10 is provided with a transmitting surface 10a through which the light L is transmitted in a surface opposing to the first main surface 4a of the light-guiding body 4. The transmitting surface 10a may be an opening portion of the frame body 10, and may be a transparent member such as glass, which is fitted in the opening portion of the frame body 10.

### First Embodiment

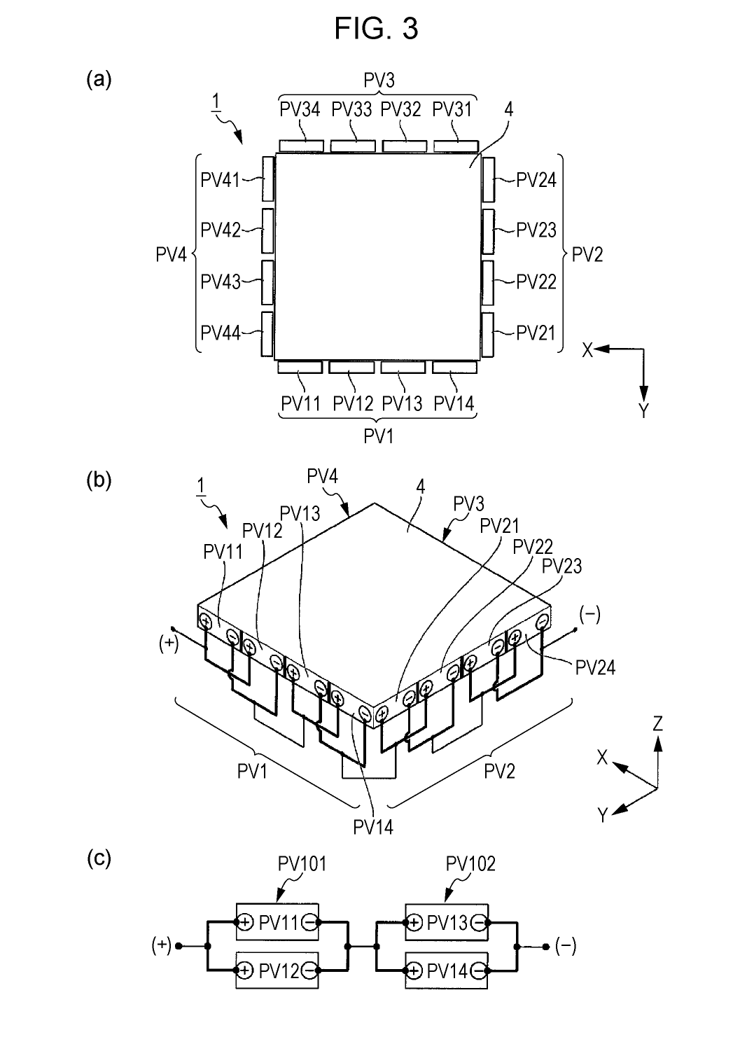

Next, description will be given for one example of an electrical connection relation of solar cells included in the above solar cell module 1 as a first embodiment with reference to FIGS. 3(a) to (c).

FIG. 3(a) is an arrangement view of each of solar cells PV11 to PV14, PV21 to PV24, PV31 to PV34 and PV41 to PV44 included in the above solar cell module 1 with respect to the light-guiding body 4.

In the first embodiment, the solar cells PV11 to PV14, PV21 to PV24, PV31 to PV34 and PV41 to PV44 included in the above solar cell module 1 are arranged in four pieces side by side on the four first end surfaces 4c of the light-guiding body 4 to thereby constitute the above four solar cell element groups PV1, PV2, PV3 and PV4.

FIG. 3(b) is a schematic wiring view of the solar cells PV11 to PV14 and PV21 to PV24 constituting the two solar cell element groups PV1 and PV2 that are arranged on the two adjacent first end surfaces 4c among the above four solar cell element groups PV1, PV2, PV3 and PV4.

Note that, in FIG. 3(b), one of electrodes provided on an inner surface (light-receiving surface) side of each of the solar cells PV11 to PV14 and PV21 to PV24 is not able to be illustrated and hence both electrodes (+) and (−) are illustrated on an outer surface side for convenience. Further, in FIG. 3(b), while the two solar cell element groups PV1 and PV2 of the above four solar cell element groups PV1, PV2, PV3 and PV4 are illustrated, the two solar cell element groups PV3 and PV4 on the opposite side thereto are not illustrated but have a structure in contrast to those of the two solar cell element groups PV1 and PV2. That is, the solar cell element group PV3 and the solar cell element group PV4 have the structure corresponding to the solar cell element group PV1 and the solar cell element group PV2, respectively.

FIG. 3(c) is an equivalent circuit of the solar cells PV11 to PV14 and PV21 to PV24 constituting the solar cell element group PV1. Note that, the remaining three solar cell element groups PV2 to PV4 basically have the same structure as that of this solar cell element group PV1, and therefore are omitted from the figure to be explained collectively.

In the structure shown in FIG. 3(c), the two adjacent solar cells P11 and PV12 and solar cells P13 and PV14 of the four solar cells PV11 to PV14 arranged side by side on the first end surface 4c of the light-guiding body 4 are respectively connected in parallel to thereby constitute two parallel-connection blocks PV101 and PV102. Further, these two parallel-connection blocks PV101 and PV102 are mutually serially connected.

Moreover, parallel-connection blocks of the two solar cell element groups (for example, PV1 and PV2 shown in FIG. 3(b)) arranged on the two adjacent first end surfaces 4c among the above four solar cell element groups PV1, PV2, PV3 and PV4 are serially connected to each other.

In the meantime, energy conversion efficiency η of the solar cell module 1 is able to be expressed by a following formula (1).

η=Voc×Isc×FF (1)

Voc: open circuit voltage
Isc: short circuit current
FF: fill factor

Since the energy conversion efficiency η shown in (1) above has a proportional relation to module output, as this energy conversion efficiency η is higher, the module output is able to be increased.

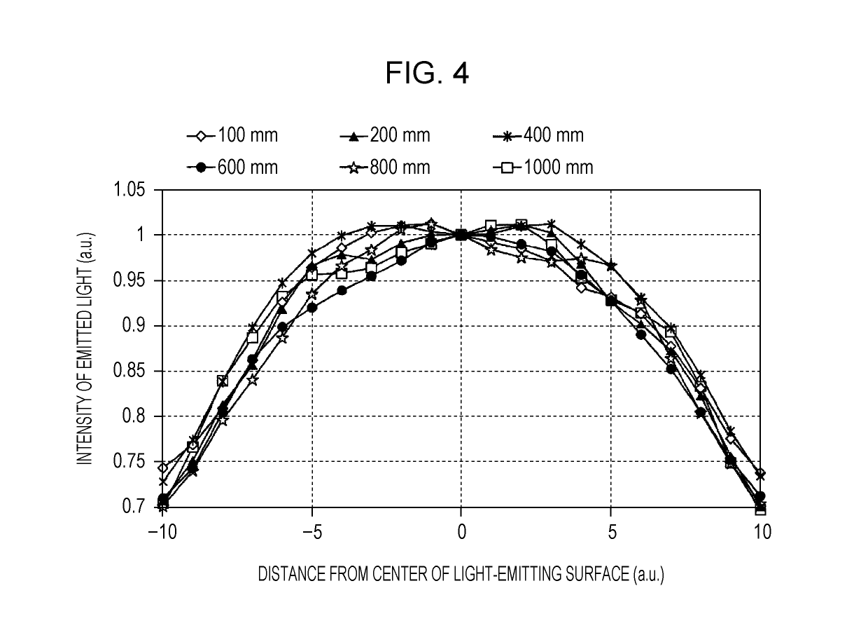

On the other hand, FIG. 4 is a graph showing results that a light intensity at a light-emitting surface (first end surface 4c) when light L is made incident from a light incidence surface (first main surface 4a) of the above light-guiding body 4 is obtained by simulation. Note that, in this simulation, the simulation was carried out by changing a size of the light-guiding body 4 in a range of 100 to 1000 nm. Moreover, a horizontal axis of the graph standardizes a center portion in an X direction of the above light-guiding body 4 as 0. On the other hand, a vertical axis of the graph standardizes an intensity of emitted light at the center portion (0) of the horizontal axis as 1.

As shown in FIG. 4, distribution is shown that the light intensity is reduced as being close to both end portions from the center portion (center portion in the X-axis direction) where the light intensity is high at the light-emitting surface. Accordingly, the light intensity received by each of the solar cells PV11 to PV14 is almost symmetrical about the center portion of the light-guiding body 4.

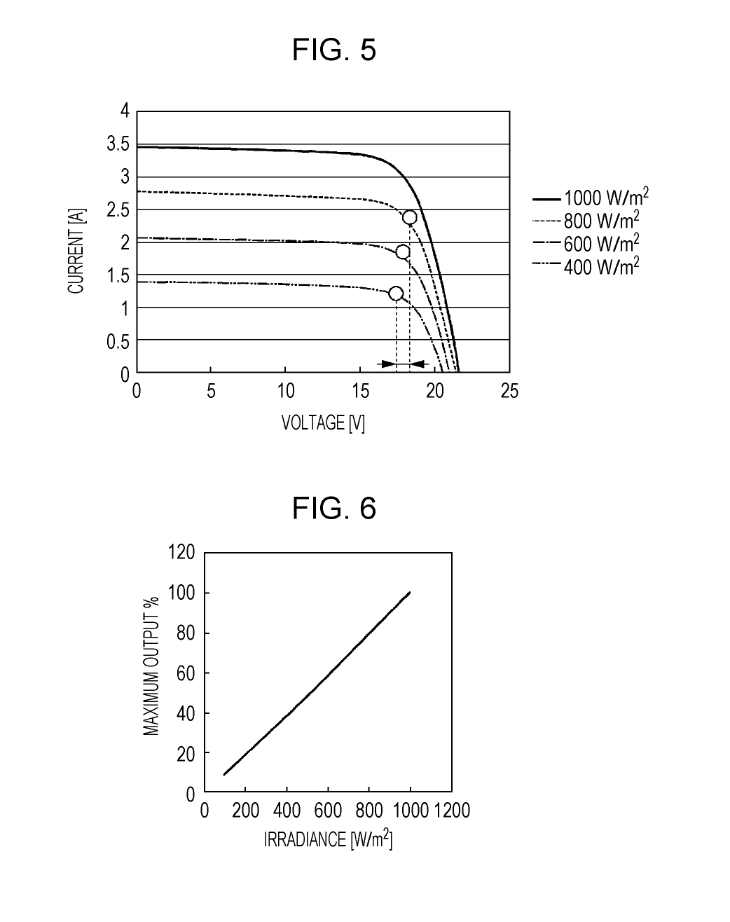

On the other hand, FIG. 5 is a graph showing results that dependency of the open circuit voltage with respect to the light intensity is measured. Note that, in this measurement, values of the voltage and the current when irradiance is changed in a range of 400 to 1000 W/m² under certain conditions of AM of 1.5 and temperature of 25° C. were measured. Note that, an intersection with an X-axis indicates the open circuit voltage Voc and an intersection with a Y-axis indicates the short circuit current Isc in each graph.

As shown in FIG. 5, it is found that the open circuit voltage has a small fluctuation width with respect to the change in the light intensity and has low dependency with respect to the light intensity.

On the other hand, FIG. 6 is a graph showing results that maximum output [%] of a solar cell when the irradiance is changed in a range of 100 to 1000 W/m² is measured.

As shown in FIG. 6, it is found that the maximum output of the solar cell is directly proportional to the irradiance.

Here, energy conversion efficiency η′ when the four solar cells PV11 to PV14 of a same type are mutually serially connected is able to be expressed by a following formula (2).

η′=(Voc1+Voc2+Voc3+Voc4)×Isc_min×FF (2)

Voc1 to Voc4: open circuit voltages of PV11 to PV14
Isc_min: minimum short circuit current among PV11 to PV14

In this case, as shown in the above formula (2), the open circuit voltage is a sum (addition) of the open circuit voltages of each of the solar cells PV11 to PV14. On the other hand, the short circuit current is rate-determined by the short circuit current of the solar cell indicating the minimum current value.

Therefore, for example, when the irradiances of the solar cells PV11/PV12/PV13/PV14 are 800/1000/1000/800 W/m², respectively, according to the above formula (2), the short circuit current Isc is rate-determined by the short circuit current of the solar cell PV1 or PV4 having the smallest irradiance of 800 W/m².

Accordingly, as to the short circuit current of the solar cell PV12 or PV13 having the irradiance of 1000 W/m², even though having a capacity which is 5/4 times larger than that of the short circuit current of the solar cell PV11 or PV14 having the irradiance of 800 W/m², the short circuit current Isc_min when the above four solar cells PV11 to PV14 are mutually serially connected is restricted to the lower short circuit current.

Therefore, when the above four solar cells PV11 to PV14 are mutually serially connected, the energy conversion efficiency η′ is greatly reduced and the module output is also reduced.

On the contrary, in the case of having the structure shown in FIG. 3(c) above, when the energy conversion efficiency by the two solar cells PV11 and PV12 (parallel-connection block PV101) is η12, the energy conversion efficiency by the two solar cells PV13 and PV14 (parallel-connection block PV102) is η34 and the energy conversion efficiency by the four solar cells PV11 to PV14 (solar cell element group PV1) is η1234, these η12, η34 and η1234 are able to be expressed by following formulas (3) to (5).

η12=Voc_min12×Isc12×FF (3)

η34=Voc_min34×Isc34×FF (4)

η1234=(Voc_min12+Voc_min34)×Isc_min_{—}1×FF (5)

Voc_min12: smaller open circuit voltage among open circuit voltages of PV1 and PV2
Voc_min34: smaller open circuit voltage among open circuit voltages of PV3 and PV4
Isc12: sum of short circuit current Isc1 of PV1 and short circuit current Isc2 of PV2 (Isc1+Isc2)
Isc34: sum of short circuit current Isc3 of PV3 and short circuit current Isc4 of PV4 (Isc3+Isc4)
Isc_min_1: smaller short circuit current among Isc12 and Isc34

First, the open circuit voltage when a plurality of solar cells are mutually connected in parallel is rate-determined by the open circuit voltage of the solar cell indicating the minimum voltage value. Therefore, the open circuit voltage Voc_min12 or Voc_min34 of the parallel-connection block PV101 or PV102 in which the above two solar cells PV11 and PV12 or PV13 and PV14 are connected in parallel is rate-determined by the open circuit voltage of the solar cell PV11 or PV14 having the lower light intensity according to the graph shown in FIG. 4.

Here, according to the results shown in FIG. 5 above, since the open circuit voltage has low dependency with respect to the light intensity, a difference between the open circuit voltage Voc1 or Voc4 of the solar cell PV11 or PV14 having the lower light intensity and the open circuit voltage Voc2 or Voc3 of the solar cell PV12 or PV13 having the higher light intensity is small. Accordingly, the open circuit voltages Voc_min12 and Voc_min34 of the above two parallel-connection blocks PV101 and PV102 are less affected by the difference of the light intensity, and further, the open circuit voltage when these two parallel-connection blocks PV101 and PV102 are serially connected is a sum of the Voc_min12 and the Voc_min34 as shown in the above formula (3).

Thus, in the case of having the structure shown in FIG. 3(c) above, a loss of the energy conversion efficiency η1234 is able to be made much smaller than the case where the above four solar cells PV1 to PV4 are mutually serially connected.

Next, the short circuit current when a plurality of solar cells are mutually connected in parallel is a sum (addition) of values of the current flowing in each of the solar cells. Therefore, the short circuit current Isc12 or Isc34 when the above two solar cells PV11 and PV12 or PV13 and PV14 are connected in parallel is a sum of the short circuit currents flowing in the two solar cells PV11 and PV12 or PV13 and PV14, Isc1+Isc2 or Isc3+Isc4.

Further, the short circuit current Isc_min_1 when the above two parallel-connection blocks PV101 and PV102 are serially connected is rate-determined by the smaller short circuit current among the above Isc12 and Isc34.

Here, according to the graph shown in FIG. 4 above, the light intensity received by each of the solar cells PV11 to PV14 is almost symmetrical about the center portion of the light-guiding body 4, and hence the Isc12 is almost equal to the Isc34 (Isc12≈Isc34).

Accordingly, a loss of the short circuit current Isc_min_1 when these two parallel-connection blocks PV101 and PV102 are serially connected is also able to be made much smaller.

As described above, in the case of having the structure shown in FIG. 3(c) above, it is possible to suppress the loss due to connection of the open circuit voltage and the short circuit current described above low, thus making it possible to increase the energy conversion efficiency thereof.

Accordingly, the solar cell module 1 in the first embodiment has such a structure with high energy conversion efficiency to thereby enable the substantial increase in the module output.

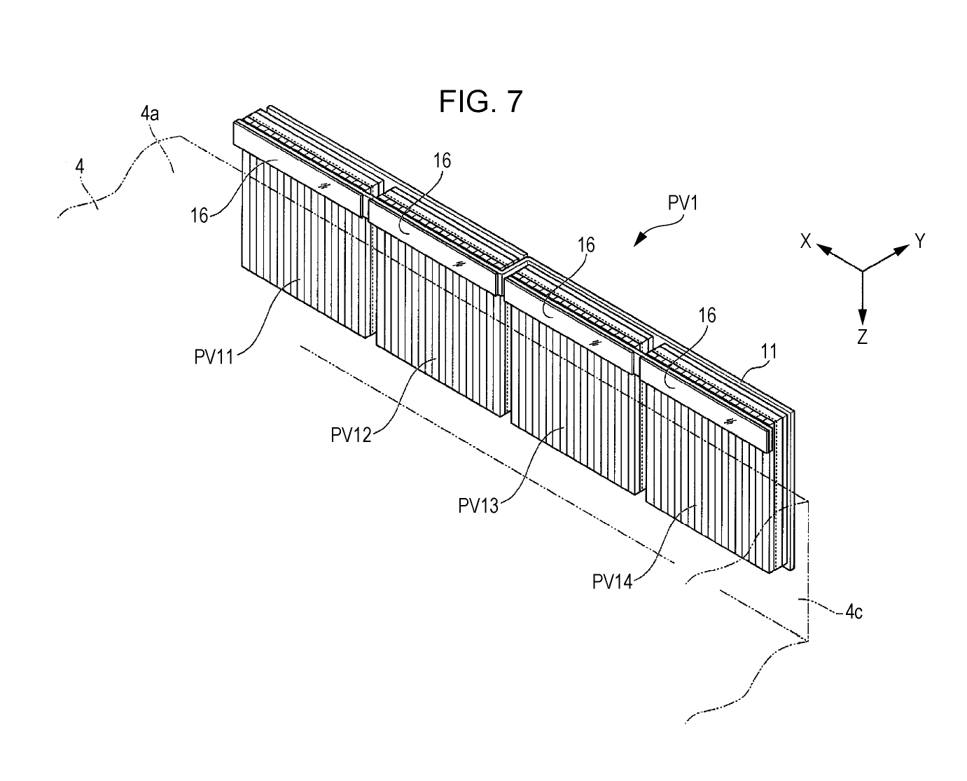

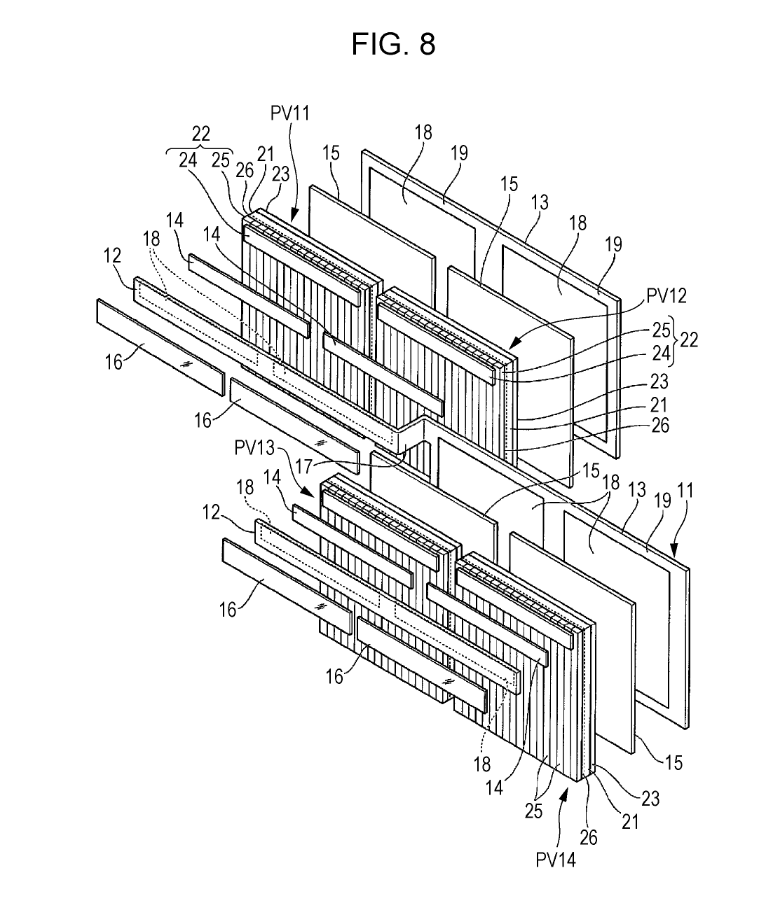

Next, description will be given for a specific structure of solar cells included in the above solar cell module 1 with reference to FIG. 7 and FIG. 8.

Note that, FIG. 7 is a partial perspective view of the solar cell element group PV1 in the first embodiment. FIG. 8 is an exploded perspective view of the solar cell element group PV1 in the first embodiment. Note that, the remaining three solar cell element groups PV2 to PV4 basically have the same structure as that of this solar cell element group PV1, and therefore are omitted from the figures to be explained collectively.

The solar cell element group PV1 includes a plurality of flexible substrates 11 on which the two adjacent solar cells P11 and PV12 and solar cells P13 and PV14 of the plurality of solar cells PV11 to PV14 which are arranged to be adjacent to each other along the first end surface 4c of the light-guiding body 4 are respectively connected in parallel, and a plurality of flexible substrates 11 on which the parallel-connection blocks PV101 and PV102 which are configured by connecting the two adjacent solar cells P11 and PV12 and solar cells P13 and PV14 respectively in parallel are serially connected to each other.

Each of the solar cells PV11 to PV14 includes a semiconductor substrate 21, finger electrodes 25 and a bus bar electrode 24, which are formed on one surface side of the semiconductor substrate 21, and a back-side electrode 23 which is formed on the other surface side of the semiconductor substrate 21.

The semiconductor substrate 21 is a P-type semiconductor substrate, for example, having a rectangular shape. As the semiconductor substrate 21, publicly known various semiconductor substrates such as a monocrystalline silicon substrate, a polycrystalline silicon substrate and a gallium-arsenide substrate are usable. An N-type impurity layer 26 is formed on one surface side of the semiconductor substrate 21, and PN junction is formed on an interface between the N-type impurity layer 26 and a P-type area of the semiconductor substrate 21.

The plurality of finger electrodes 25 are formed to be adjacent to each other along one side of the semiconductor substrate 21 on a front surface of the N-type impurity layer 26. The bus bar electrode 24 by which these plurality of finger electrodes 25 are connected is formed on one end side of the plurality of finger electrodes 25. The bus bar electrode 24 is formed in a stripe manner along the above one side of the semiconductor substrate 21 so as to extend across the plurality of finger electrodes 25. A first current-collecting electrode 22 is formed by the plurality of finger electrodes 25 and the bus bar electrode 24. The back-side electrode 23 as a second current-collecting electrode is formed on the other surface side of the semiconductor substrate 21 so as to almost cover the entire other surface of the semiconductor substrate 21.

The flexible substrates 11 are flexible wiring substrates (Flexible printed circuits; FPC) formed by laminating a conductive layer 18 on an insulating film 19. Used as the flexible substrate 11 is, for example, one in which upper and lower surfaces of the conductive layer 18 such as copper foil are covered with the insulating film 19 such as polyimide and a part of the insulating film 19, which is connected to the solar cells PV11 to PV14, is removed to expose the conductive layer 18.

The flexible substrate 11 includes a first electrode unit 12 that is connected to the bus bar electrode 24, a second electrode unit 13 that is connected to the back-side electrode 23, and a connection unit 17 by which the first electrode unit 12 and the second electrode unit 13 are connected.

In the flexible substrate 11, the first electrode unit 12 at one end side thereof is connected to the bus bar electrodes 24 of the two adjacent solar cells PV11 and PV12, and the second electrode unit 13 at the other end side thereof and the connection unit 17 are bent along an end surface of the solar cell PV2 to be connected to the back-side electrodes 23 of the two adjacent solar cells PV13 and PV14. The connection unit 17 is bent at a substantially right angle along end surfaces of the two adjacent solar cells PV2 and PV3 so that a large gap is not generated between these solar cells PV2 and PV3.

The flexible substrate 11 is connected to the bus bar electrode 24 and the back-side electrode 23 by using conductive films 14 and 15. The conductive films 14 and 15 are obtained by dispersing fine conductive particles into the inside of a resin to mold in a film shape having thickness from about 10 μm to 100 μm. As the conductive films 14 and 15, an anisotropic conductive film (ACF) and the like are usable, and not only one having conductive property only in a thickness direction like the anisotropic conductive film but also one having conductive property in both the thickness direction and a direction which is perpendicular thereto are usable.

A reflection layer 16 that reflects light incident from the first end surface 4c of the light-guiding body 4 is provided on a surface opposing to the first end surface 4c of the light-guiding body 4 in the flexible substrate 11. By providing the reflection layer 16, absorption of the light by the flexible substrate 11 is suppressed, thus making it possible to use the light from the light-guiding body 4 for power generation effectively.

Note that, the present invention is not necessarily limited to the above first embodiment, and may be variously modified without departing from the gist of the present invention.

For example, the solar cell module 1 shown in the above first embodiment has been explained by taking a case where the number of the solar cells N is 16 (=4 pieces×4 sides) and the number of the parallel-connection blocks L is 8 (=2 pieces×4 sides) as an example. However, the number of the solar cells N and the number of the parallel-connection blocks L are able to be changed according to a design of the above solar cell module 1.

That is, the solar cell module 1 shown as the above first embodiment merely may have a structure that N (N is an integer of 4 or more) solar cells of a same type are connected in parallel in a plurality of pieces to thereby form L (L is an integer of 2 or more) parallel-connection blocks, and further these L parallel-connection blocks are mutually serially connected.

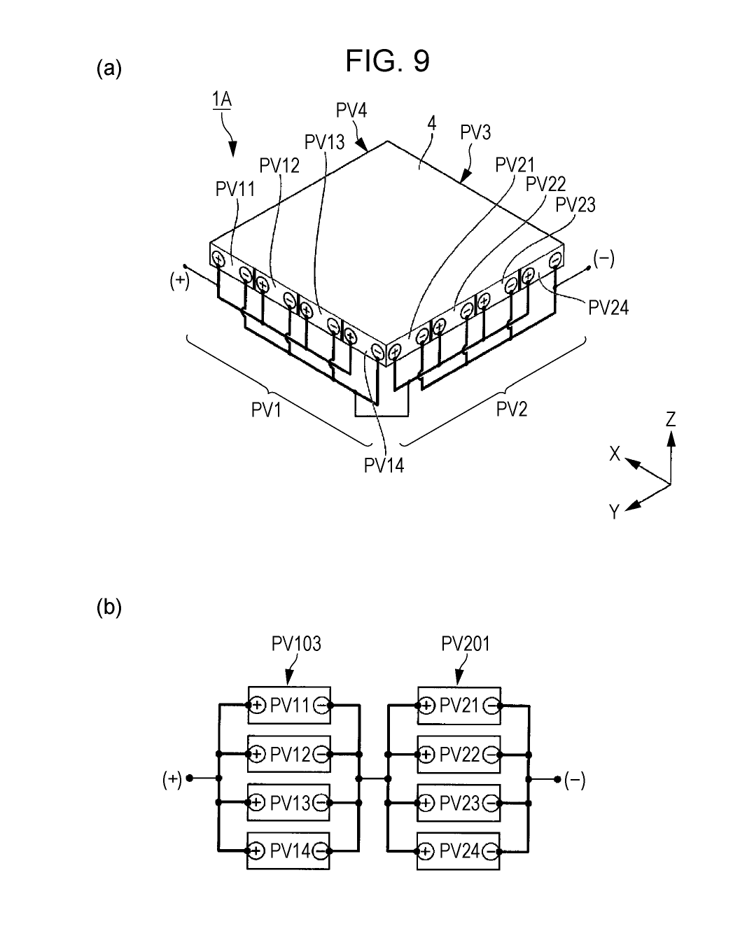

Accordingly, a solar cell module 1A having a structure as shown in FIG. 9, for example, is also allowed.

Specifically, FIG. 9(a) is a schematic wiring view of the solar cells PV11 to PV14 and PV21 to PV24 constituting the two solar cell element groups PV1 and PV2 that are arranged on the two adjacent first end surfaces 4c in the above two solar cell element groups PV1 and PV2.

Note that, in FIG. 9(a), one of electrodes provided on the inner surface (light-receiving surface) side of each of the solar cells PV11 to PV14 and PV21 to PV24 is not able to be illustrated and hence both electrodes (+) and (−) are illustrated on the outer surface side for convenience. Further, in FIG. 9(a), while the two solar cell element groups PV1 and PV2 of the four solar cell element groups PV1, PV2, PV3 and PV4 are illustrated, the two solar cell element groups PV3 and PV4 on the opposite side thereto are not illustrated but have a structure in contrast to those of the two solar cell element groups PV1 and PV2. That is, the solar cell element group PV3 and the solar cell element group PV4 have the structure corresponding to the solar cell element group PV1 and the solar cell element group PV2, respectively.

FIG. 9(b) is an equivalent circuit of the solar cells PV11 to PV14 and PV21 to PV24 constituting the solar cell element group PV1. Note that, the remaining three solar cell element groups PV2 to PV4 basically have the same structure as that of this solar cell element group PV1, and therefore are omitted from the figure to be explained collectively.

In the structure shown in FIG. 9(b), the four solar cells PV11 to PV14 arranged side by side on the first end surface 4c of the light-guiding body 4 are respectively connected in parallel to thereby constitute one parallel-connection block PV103.

Moreover, the parallel-connection blocks PV103 and PV201 of two solar cell element groups (for example, PV1 and PV2 shown in FIG. 9(a)) arranged on the two adjacent first end surfaces 4c among the above four solar cell element groups PV1, PV2, PV3 and PV4 are serially connected to each other.

Here, in the case of having the structure shown in FIG. 9(b) above, when the energy conversion efficiency by the four solar cells PV11 to PV14 (parallel-connection block PV103) is η_{(PV11-PV14)}, the energy conversion efficiency by the four solar cells PV21 to PV24 (parallel-connection block PV201) is η_{(PV21-PV24)}, and the energy conversion efficiency by the eight solar cells PV11 to PV14 and PV21 to PV24 (parallel-connection blocks PV103 and PV201) is η_{(PV103-PV201)}, these η_{(PV11-PV14)}, η_{(PV21-PV24)} and η_{(PV103-PV201)} are able to be expressed by following formulas (6) to (8).

η_{(PV11-PV14)}=Voc_min_{(PV11-PV14)}×Isc_{(PV11-PV14)}×FF (6),

η_{(PV21-PV24)}=Voc_min_{(PV21-PV24)}×Isc_{(PV21-PV24)}×FF (7),

η_{(PV103-PV201)}={Voc_min_{(PV11-PV14)}+Voc_min_{(PV21-PV24)}}×Isc_min_{—}2×FF (8)

Voc_min_{(PV11-PV14)}: minimum open circuit voltage among open circuit voltages of PV11 to PV14
Voc_min_{(PV21-PV24)}: minimum open circuit voltage among open circuit voltages of PV21 to PV24
Isc_{(PV11-PV14)}: sum of short circuit currents of PV11 to PV14
Isc_{(PV21-PV24)}: sum of short circuit currents of PV21 to PV24
Isc_min_2: smaller short circuit current among Isc_{(PV11-PV14)} and Isc_{(PV21-PV24)}

As described above, the open circuit voltage when a plurality of solar cells are mutually connected in parallel is rate-determined by the open circuit voltage of the solar cell indicating the minimum voltage value, but has low dependency with respect to the light intensity, and therefore the open circuit voltages Voc_min_{(PV11-PV14)} and Voc_min_{(PV21-PV24)} of the parallel-connection blocks PV203 and PV201 are less affected by the difference of the light intensity. Further, the open circuit voltage when these two parallel-connection blocks PV203 and PV201 are serially connected is a sum of the Voc_min_{(PV11-PV14)} and the Voc_min_{(PV21-PV24)} as shown in the above formula (8).

Thus, in the case of having the structure shown in FIG. 9(b) above, a loss of the energy conversion efficiency η_{(PV103-PV201)} is able to be made much smaller.

As described above, the short circuit current when a plurality of solar cells are mutually connected in parallel is a sum (addition) of values of the current flowing in each of the solar cells, and therefore, the short circuit current Isc_{(PV11-PV14)} or Isc_{(PV21-PV24)} when the above four solar cells PV11 to PV14 or PV21 to PV24 are connected in parallel is a sum of the short circuit currents flowing in the above four solar cells PV11 to PV14 or PV21 to PV24.

Further, the short circuit current Isc_min_1 when the above two parallel-connection blocks PV101 and PV102 are serially connected is rate-determined by the smaller short circuit current among the above Isc_{(PV11-PV14)} and the Isc_{(PV21-PV24)}.

Here, according to the graph shown in FIG. 4 above, the light intensity received by each of the solar cells PV11 to PV14 or PV21 to PV24 is almost symmetrical about the center portion of the light-guiding body 4, and hence the Isc_{(PV11-PV14)} is almost equal to the Isc_{(PV21-PV24)}.

Accordingly, a loss of the short circuit current Isc_min_2 when these two parallel-connection blocks PV203 and PV201 are serially connected is also able to be made much smaller.

As described above, in the case of having the structure shown in FIG. 9 above as well, it is possible to suppress the loss due to connection of the open circuit voltage and the short circuit current described above low, thus making it possible to increase the energy conversion efficiency thereof.

Accordingly, the above solar cell module 1A has such a structure with high energy conversion efficiency to thereby enable the substantial increase in the module output.

Note that, when all of the plurality of solar cells are mutually connected in parallel (in the case of L=1), an output current increases and power loss increases (P_loss=RI²). For suppressing this loss, wiring for connection between the solar cells becomes large in thickness and manufacturing costs of the solar cell module increase.

Moreover, in the solar cell modules 1 and 1A shown in the above first embodiment, when each short circuit current of the N solar cells in the case of making the exterior light incident on the entire light incidence surface uniformly is Iⱼ (j is an integer from 1 to N), a sum of short circuit currents of the plurality of solar cells included in each parallel-connection block of the L parallel-connection blocks is ITᵢ (i is an integer from 1 to L), a difference, among arbitrary two of the parallel-connection blocks selected from the L parallel-connection blocks, between the IT is of the two parallel-connection blocks that have a greatest difference between the ITᵢs is ID₁, and a difference, among arbitrary two of the solar cells selected from the N solar cells, between the Iⱼs of the two solar cells that have a greatest difference between the Iⱼs is ID₂, it is desired to satisfy a relational expression of ID₁<ID₂.

For example, in the case of the solar cell module 1 shown in FIG. 3 above, when the short circuit currents of the solar cells PV11, PV12, PV13 and PV14 are I₁, I₂, I₃ and I₄, respectively, a relation of I₁<I₂=I₃>I₄ is satisfied.

Further, when the short circuit currents of the above two parallel-connection blocks PV101 and PV102 are IT₁ and IT₂, respectively, as to the difference ID₁ between the short circuit currents of these two parallel-connection blocks, ID₁=|IT₁−IT₂|=0 because a relation of IT₁=IT₂ is satisfied.

On the other hand, a combination of the two solar cells that have the greatest difference of the short circuit currents among the short circuit currents of the above four solar cells PV11, PV12, PV13 and PV14 is a combination of PV11 and PV12 or a combination of PV13 and PV14. Accordingly, as to the difference ID₂ between the short circuit currents of these two solar cells that have the greatest difference of the short circuit currents, ID₂=|I₁−I₂|=I₃−I₄|>0.

This shows that a relational expression of ID₁<ID₂ is satisfied in the solar cell module 1 shown in FIG. 3 above. Accordingly, by satisfying the above relation, the solar cell module 1 shown in FIG. 3 above is able to suppress the loss due to connection of the open circuit voltage and the short circuit current described above low, thus making it possible to increase the energy conversion efficiency thereof.

Similarly, in the case of the solar cell module 1A shown in FIG. 9 above, the short circuit currents of the solar cells PV11, PV12, PV13, PV14, PV21, PV22, PV23 and PV24 are I₁, I₂, I₃, I₄, I₅, I₆, I₇ and I₈, respectively, a relation of I₁<I₂=I₃>I₄=I₅<I₆=I₇>I₈ is satisfied.

Further, when the short circuit currents of the above two parallel-connection blocks PV103 and PV201 are IT₁ and IT₂, respectively, as to the difference ID₁ between the short circuit currents of these two parallel-connection blocks, ID₁=|IT₁−IT₂|=0 because a relation of IT₁=IT₂ is satisfied.

On the other hand, a combination of the two solar cells that have the greatest difference of the short circuit currents among the short circuit currents of the above eight solar cells PV11, PV12, PV13, PV14, PV21, PV22, PV23 and PV24 is a combination of PV11 and PV12, a combination of PV13 and PV14, a combination of PV21 and PV22, or a combination of PV23 and PV24. Accordingly, as to the difference ID₂ between the short circuit currents of these two solar cells that have the greatest difference of the short circuit currents, ID₂=|I₁−I₂|=|I₃−I₄|=|I₅−I₆|=|I₇−I₈|>0.

This shows that a relational expression of ID₁<ID₂ is satisfied in the solar cell module 1A shown in FIG. 9 above. Accordingly, by satisfying the above relation, the solar cell module 1A shown in FIG. 3 above is able to suppress the loss due to connection of the open circuit voltage and the short circuit current described above low, thus making it possible to increase the energy conversion efficiency thereof.

Moreover, in the above first embodiment, the light-guiding body 4 may be any plate-shaped body having at least one or more side, and the N solar cells may have any structure of being arranged side by side along at least one side of this light-guiding body 4.

In this case, it is desired that the solar cell that is arranged at one end portion in an arrangement direction of the N solar cells and the solar cell that is arranged at the other end portion among the N solar cells are included in the parallel-connection blocks which are different from each other.

For example, in the solar cell module 1 shown in FIG. 3 above, the solar cell PV11 that is arranged at one end portion and the solar cell PV14 that is arranged at the other end portion are included in one parallel-connection block PV101 and the other parallel-connection block PV102, respectively.

This makes it possible to suppress the loss due to connection of the open circuit voltage and the short circuit current described above low, thus making it possible to increase the energy conversion efficiency thereof.

### Second Embodiment

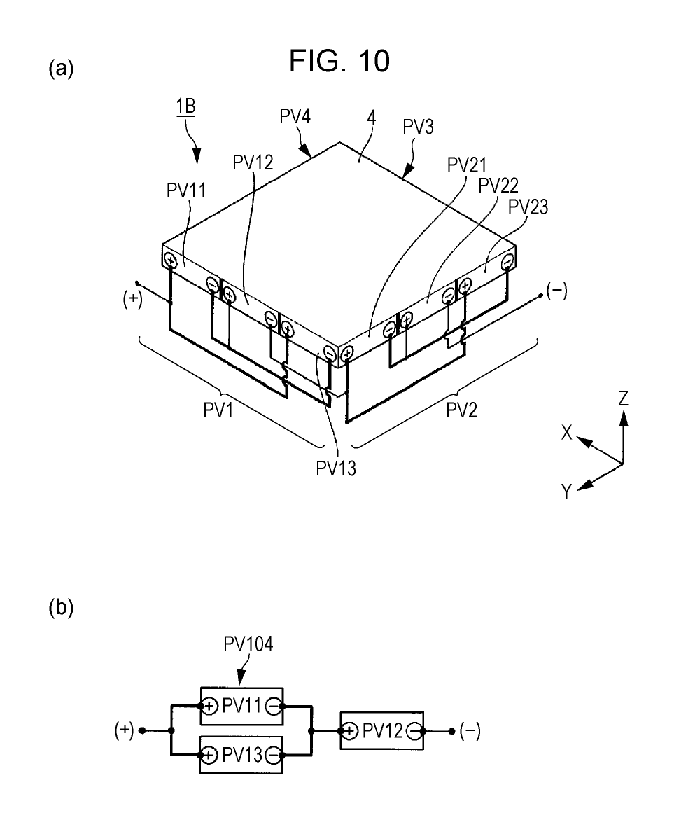

Next, description will be given for an electrical connection relation of solar cells included in a solar cell module 1B as a second embodiment with reference to FIGS. 10(a) and (b). Note that, in the following description, description for parts same as those of the solar cell modules 1 and 1A shown in the above first embodiment are omitted and the same reference numerals are assigned thereto in the figures.

FIG. 10(a) is a schematic wiring view of the solar cells included in the solar cell module 1B shown in the second embodiment.

The solar cell module 1B shown in the second embodiment includes the six solar cells PV11 to PV13 and PV21 to PV23 constituting the two solar cell element groups PV1 and PV2 that are arranged on the two adjacent first end surfaces 4c among the four solar cell element groups PV1, PV2, PV3 and PV4 that are arranged on the four first end surfaces 4c of the above light-guiding body 4. That is, these six solar cells PV11 to PV13 and PV21 to PV23 are arranged side by side in three pieces on the two first end surfaces 4c of the light-guiding body 4 to thereby constitute the two solar cell element groups PV1 and PV2.

Note that, in FIG. 10(a), one of electrodes provided on the inner surface (light-receiving surface) side of each of the solar cells PV11 to PV13 and PV21 to PV23 is not able to be illustrated and hence both electrodes (+) and (−) are illustrated on the outer surface side for convenience. Further, in FIG. 10(a), while the above two solar cell element groups PV1 and PV2 of the four solar cell element groups PV1, PV2, PV3 and PV4 are illustrated, the two solar cell element groups PV3 and PV4 on the opposite side thereto are not illustrated but have a structure in contrast to those of the two solar cell element groups PV1 and PV2. That is, the solar cell element group PV3 and the solar cell element group PV4 have the structure corresponding to the solar cell element group PV1 and the solar cell element group PV2, respectively.

FIG. 10(b) is an equivalent circuit of the solar cells PV11 to PV13 constituting the solar cell element group PV1. Note that, the remaining three solar cell element groups PV2 to PV4 basically have the same structure as that of this solar cell element group PV1, and therefore are omitted from the figure to be explained collectively.

In the structure shown in FIG. 10(b), the two solar cells PV11 and PV13 among the three solar cells PV11 to PV13 arranged side by side on the first end surface 4c of the light-guiding body 4 are connected in parallel to thereby constitute one parallel-connection block PV104. Further, this one parallel-connection block PV104 and the remaining one solar cell PV12 are serially connected.

Moreover, as shown in FIG. 10(a), the solar cell PV12 constituting the above solar cell element group PV1 and the parallel-connection block PV constituting the above solar cell element group PV2 are serially connected.

Here, in the case of having the structure shown in FIG. 10(b) above, when the energy conversion efficiency by the two solar cells PV11 and PV13 (parallel-connection block PV104) is η104, and the energy conversion efficiency by the three solar cells PV11 to PV13 (solar cell element group PV1) is η123, these η104 and η123 are able to be expressed by following formulas (9) and (10).

η104=Voc_min13×Isc13×FF (9)

η123=(Voc_min13+Voc2)×Isc_min_3×FF (10)

Voc_min12: smaller open circuit voltage among open circuit voltages of PV1 and PV2
Voc3: open circuit voltage of PV3
Isc_min_3: smaller short circuit current among Isc12 and Isc3

As described above, the open circuit voltage when a plurality of solar cells are mutually connected in parallel is rate-determined by the open circuit voltage of the solar cell indicating the minimum voltage value, but has low dependency with respect to the light intensity, and therefore the open circuit voltage Voc_min12 of the parallel-connection block PV104 is less affected by the difference of the light intensity. Further, the open circuit voltage when this parallel-connection block PV104 and the solar cell PV13 are serially connected is a sum of the Voc_min12 and the Voc3 as shown in the above formula (10).

Thus, in the case of having the structure shown in FIG. 10(b) above, a loss of the energy conversion efficiency η123 is able to be made much smaller.

As described above, the short circuit current when a plurality of solar cells are mutually connected in parallel is a sum (addition) of values of the current flowing in each of the solar cells, and therefore, the short circuit current Isc13 when the above two solar cells PV11 and PV13 are connected in parallel is a sum of the short circuit currents Isc1 and Isc3 flowing in the above two solar cells PV11 and 13 (Isc1+Isc3).

Further, the short circuit current Isc_min_3 when this parallel-connection block PV104 and the solar cell PV12 are serially connected is rate-determined by the smaller short-circuit current among the above Isc13 and Isc2.

Here, according to comparison to the light intensity received by each of the solar cells PV11 to PV13, the short circuit current Isc2 of the solar cell PV12 arranged at the center portion of the light-guiding body 4 is the highest and the short circuit currents Isc1 and Isc3 of the remaining two solar cells PV11 and PV13 are almost symmetrical about the center portion of the light-guiding body 4, and hence are almost equal (Isc2>Isc1≈Isc3).

Accordingly, when the Isc13 (Isc1+Isc3) is compared to the Isc2, a difference therebetween is small, so that a loss of the short circuit current Isc_min_3 when the parallel-connection block PV104 and the solar cell PV12 are serially connected is also able to be made much smaller.

As described above, in the case of having the structure shown in FIG. 10 above, it is possible to suppress the loss due to connection of the open circuit voltage and the short circuit current described above low, thus making it possible to increase the energy conversion efficiency thereof.

Accordingly, the solar cell module 1B in the second embodiment has such a structure with high energy conversion efficiency to thereby enable the substantial increase in the module output.

Note that, the present invention is not necessarily limited to the above second embodiment, and may be variously modified without departing from the gist of the present invention.

For example, the solar cell module 1B shown in the above second embodiment has been explained by taking a case where the two solar cells of the three solar cells are connected in parallel to thereby form one parallel-connection block, and further this parallel-connection block and the remaining one solar cell are serially connected as an example. However, the number of the solar cells N and the number of the parallel-connection blocks L are able to be changed according to a design of the above solar cell module 1B.

That is, the solar cell module 1B shown as the above second embodiment merely may have a structure that M (M is an integer larger than 1 and smaller than N) solar cells of N (N is an integer of 3 or more) solar cells of a same type are connected in parallel in a plurality of pieces, to thereby form L (L is an integer of 1 or more) parallel-connection blocks each of which has the plurality of solar cells mutually connected in parallel, and further these L parallel-connection blocks and the remaining (N-M) solar cell are mutually serially connected.

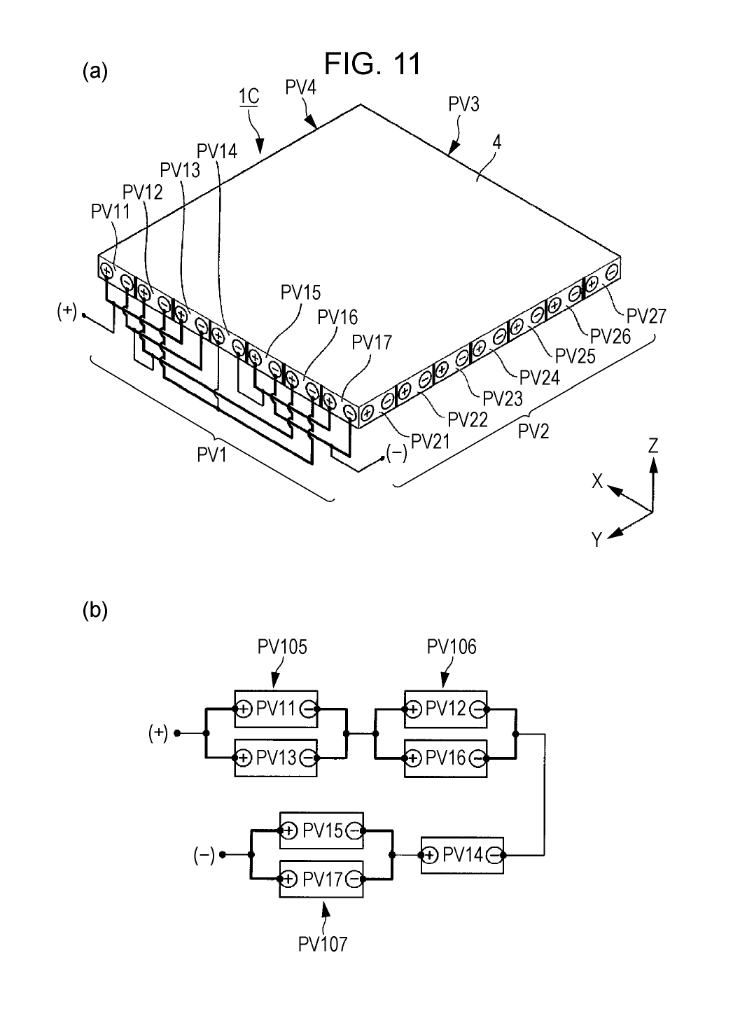

Accordingly, a solar cell module 1C having a structure as shown in FIG. 11, for example, is also allowed.

Specifically, FIG. 11(a) is a schematic wiring view of the solar cells PV11 to PV17 and PV21 to PV27 constituting the two solar cell element groups PV1 and PV2 that are arranged on the two adjacent first end surfaces 4c among the above two solar cell element groups PV1 and PV2.

Note that, in FIG. 11(a), one of electrodes provided on the inner surface (light-receiving surface) side of each of the solar cells PV11 to PV17 and PV21 to PV27 is not able to be illustrated and hence both electrodes (+) and (−) are illustrated on the outer surface side for convenience. Further, in FIG. 11(a), while the above two solar cell element groups PV1 and PV2 of the four solar cell element groups PV1, PV2, PV3 and PV4 are illustrated, the two solar cell element groups PV3 and PV4 on the opposite side thereto are not illustrated but have a structure in contrast to those of the two solar cell element groups PV1 and PV2. That is, the solar cell element group PV3 and the solar cell element group PV4 have the structure corresponding to the solar cell element group PV1 and the solar cell element group PV2, respectively.

FIG. 11(b) is an equivalent circuit of the solar cells PV11 to PV17 constituting the solar cell element group PV1. Note that, the remaining three solar cell element groups PV2 to PV4 basically have the same structure as that of this solar cell element group PV1, and therefore are omitted from the figure to be explained collectively.

In the structure shown in FIG. 11(b), the six solar cells PV11 to PV13 and PV15 to PV17 of the seven solar cells PV11 to PV17 arranged side by side on the first end surface 4c of the light-guiding body 4 are connected in parallel in two pieces to thereby constitute three parallel-connection blocks PV105, PV106 and PV107. Further, these three parallel-connection blocks PV104 and the remaining one solar cell PV14 are serially connected.

Here, in the case of having the structure shown in FIG. 11(b) above, when the energy conversion efficiency by the two solar cells PV11 and PV13 (parallel-connection block PV104) is η105, the energy conversion efficiency by the two solar cells PV12 and PV16 (parallel-connection block PV106) is η106, the energy conversion efficiency by the two solar cells PV15 and PV17 (parallel-connection block PV107) is η107, and the energy conversion efficiency by the seven solar cells PV11 to PV17 (solar cell element group PV1) is η1-8, these η105, η106, η107 and η1-8 are able to be expressed by following formulas (11) to (14).

η105=Voc_min13×Isc13×FF (11)

η106=Voc_min26×Isc26×FF (12)

η107=Voc_min57×Isc57×FF (13)

η1-8=(Voc_min13+Voc_min26+Voc_min57+Voc4)×Isc_min_{—}4×FF (14)

Voc_min13: smaller open circuit voltage among open circuit voltages of PV1 and PV3
Voc_min26: smaller open circuit voltage among open circuit voltages of PV2 and PV6
Voc_min57: smaller open circuit voltage among open circuit voltages of PV5 and PV7
Voc4: open circuit voltage of PV4
Isc_min_4: smaller short circuit current among Isc13, Isc26, Isc57 and Isc4

As described above, the open circuit voltage when a plurality of solar cells are mutually connected in parallel is rate-determined by the open circuit voltage of the solar cell indicating the minimum voltage value, but has low dependency with respect to the light intensity, and therefore the open circuit voltages Voc_min13, Voc_min26 and Voc_min57 of the parallel-connection block PV104 are less affected by the difference of the light intensity. Further, the open circuit voltage when these three parallel-connection blocks PV105 to 107 and the solar cell PV14 are serially connected is a sum of the Voc_min13, the Voc_min26, the Voc_min57 and the Voc4 as shown in the above formula (14).

Thus, in the case of having the structure shown in FIG. 11(b) above, a loss of the energy conversion efficiency η1-8 is able to be made much smaller.

As described above, the short circuit current when a plurality of solar cells are mutually connected in parallel is a sum (addition) of values of the current flowing in each of the solar cells, and therefore, the short circuit current Isc13 when the above two solar cells PV11 and PV13 are connected in parallel is a sum of the short circuit currents Isc1 and Isc3 flowing in the above two solar cells PV11 and 13 (Isc1+Isc3). Similarly, the short circuit current Isc26 when the above two solar cells PV12 and PV16 are connected in parallel is a sum of the short circuit currents Isc2 and Isc6 flowing in the above two solar cells PV12 and 16 (Isc2+Isc6). Similarly, the short circuit current Isc57 when the above two solar cells PV15 and PV17 are connected in parallel is a sum of the short circuit currents Isc5 and Isc7 flowing in the above two solar cells PV15 and 17 (Isc5+Isc7).

Further, the short circuit current Isc_min_4 when these three parallel-connection blocks PV105 to 107 and the solar cell PV14 are serially connected is rate-determined by the minimum short circuit current among the above Isc13, Isc26, Isc57 and Isc4.

Here, according to comparison to the light intensity received by each of the solar cells PV11 to PV17, the short circuit current Isc4 of the solar cell PV14 arranged at the center portion of the light-guiding body 4 is the highest, then, the short circuit currents Isc3 and Isc5 of the solar cells PV13 and PV15 that are arranged to be almost symmetrical about the center portion of the light-guiding body 4 are almost equal, the short circuit currents Isc2 and Isc6 of the solar cells PV12 and PV16 are almost equal, and the short circuit currents Isc1 and Isc7 of the solar cells PV11 and PV17 are almost equal, so that the short circuit current is reduced as being close to both end portions from the center portion of the light-guiding body 4 (Isc4>Isc3≈Isc5>Isc2≈Isc6>Isc1≈Isc7).

Accordingly, when the above Isc13, Isc26, Isc57 and Isc4 are compared, differences therebetween are small (averaged), so that a loss of the short circuit current Isc_min_4 when these three parallel-connection blocks PV105 to 107 and the solar cell PV14 are serially connected is also able to be made much smaller.

As above, in the case of having the structure shown in FIG. 11 above, it is possible to suppress the loss due to connection of the open circuit voltage and the short circuit current described above low, thus making it possible to increase the energy conversion efficiency thereof.

Accordingly, the above solar cell module 1C has such a structure with high energy conversion efficiency to thereby enable the substantial increase in the module output.

Moreover, in the solar cell module 1C shown in the above second embodiment, when each short circuit current of the N solar cells in the case of making the exterior light incident on the entire light incidence surface uniformly is Iⱼ (j is an integer from 1 to N), a sum of short circuit currents of the plurality of solar cells included in each parallel-connection block of the L parallel-connection blocks is ITᵢ (i is an integer from 1 to L), a difference, among arbitrary two of the parallel-connection blocks selected from the L parallel-connection blocks, between the ITᵢs of the two parallel-connection blocks that have a greatest difference between the ITᵢs is ID₁, a difference, among arbitrary two of the solar cells selected from the N solar cells, between the Iⱼs of the two solar cells that have a greatest difference between the Iⱼs is ID₂, and a difference, among arbitrary one of the parallel-connection block selected from the L parallel-connection blocks and arbitrary one of the solar cell selected from the (N-M) solar cell, between the ITᵢ and the Iⱼ of the one parallel connection block and the one solar cell that have a greatest difference between the ITᵢ and the Iⱼ is ID₃, it is desired to satisfy relational expressions of ID₁<ID₂ and ID₃<ID₂.

For example, in the case of the solar cell module 1C shown in FIG. 11 above, when the short circuit currents of the solar cells PV11, PV12, PV13, PV14, PV15, PV16 and PV17 are I₁, I₂, I₃, I₄, I₅, I₆ and I₇, respectively, a relation of I₁=I₇<I₂=I₆<I₃=I₅<I₄ is satisfied.

Further, when the short circuit currents of the above three parallel-connection blocks PV105, PV106 and PV107 are IT₁, IT₂ and IT₃, respectively, a relation of IT₁=IT₃<IT₂ is satisfied. Accordingly, a combination of the two parallel-connection blocks that have the greatest difference of the short circuit currents is a combination of PV105 and PV106 or a combination of PV106 and PV107. Further, as to the difference ID₁ between the short circuit currents of these two parallel-connection blocks, ID₁=|IT₁−IT₂|=|IT₃−IT₂|.

On the other hand, a combination of the two solar cells that have the greatest difference of the short circuit currents among the short circuit currents of the above seven solar cells PV11, PV12, PV13, PV14, PV15, PV16 and PV17 is a combination of PV11 and PV14 or a combination of PV14 and PV17. Accordingly, as to the difference ID₂ between the short circuit currents of these two solar cells that have the greatest difference of the short circuit currents, ID₂=|I₁−I₄|=|I₇−I₄|.

Further, a combination of the parallel-connection block and the solar cell that have the greatest difference of the short circuit currents among the short circuit currents IT₁, IT₂ and IT₃ of the above three parallel-connection blocks PV105, PV106 and PV107 and the short circuit current I₄ of the one solar cell PV4 is a combination of PV105 and PV4 or a combination of PV107 and PV4. Accordingly, as to the difference ID₃ between the short circuit currents of the parallel-connection blocks PV105 and PV107 and the solar cell PV4 that have the greatest difference of the short circuit currents, ID₃=|IT₁−I₄|=|IT₃−I₄|.

This shows that the relational expressions of ID₁<ID₂ and ID₃ 135<ID₂ are satisfied in the solar cell module 1C shown in FIG. 11 above. Accordingly, by satisfying the above relations, the solar cell module 1C shown in FIG. 11 above is able to suppress the loss due to connection of the open circuit voltage and the short circuit current described above low, thus making it possible to increase the energy conversion efficiency thereof.

Moreover, in the solar cell module 1C shown in the above second embodiment, when each short circuit current of the N solar cells in the case of making the exterior light incident on the entire light incidence surface uniformly is Iⱼ (j is an integer from 1 to N), the solar cell having the minimum Iⱼ is desired to be included in any of the L parallel-connection blocks.

For example, in the solar cell module 1C shown in FIG. 11 above, the solar cells PV11 and PV7 having the minimum short circuit current are included in the parallel-connection blocks PV105 and PV107, respectively.

This makes it possible to suppress the loss due to connection of the open circuit voltage and the short circuit current described above low, thus making it possible to increase the energy conversion efficiency thereof.

Moreover, in the above second embodiment, the light-guiding body 4 may be any plate-shaped body having at least one or more side, and the N solar cells may have any structure of being arranged side by side along at least one side of this light-guiding body 4.

In this case, at least one of the solar cell that is arranged at one end portion in an arrangement direction of the N solar cells and the solar cell that is arranged at the other end portion among the N solar cells is desired to be included in any of the L parallel-connection blocks.

For example, in the solar cell module 1B shown in FIG. 10 above, the solar cell PV11 that is arranged at one end portion is included in the parallel-connection block PV104. On the other hand, in the solar cell module 1C shown in FIG. 11 above, the solar cells PV11 and PV7 having the minimum short circuit current are included in the parallel-connection blocks PV105 and PV107, respectively.

This makes it possible to suppress the loss due to connection of the open circuit voltage and the short circuit current described above low, thus making it possible to increase the energy conversion efficiency thereof.

### Third Embodiment

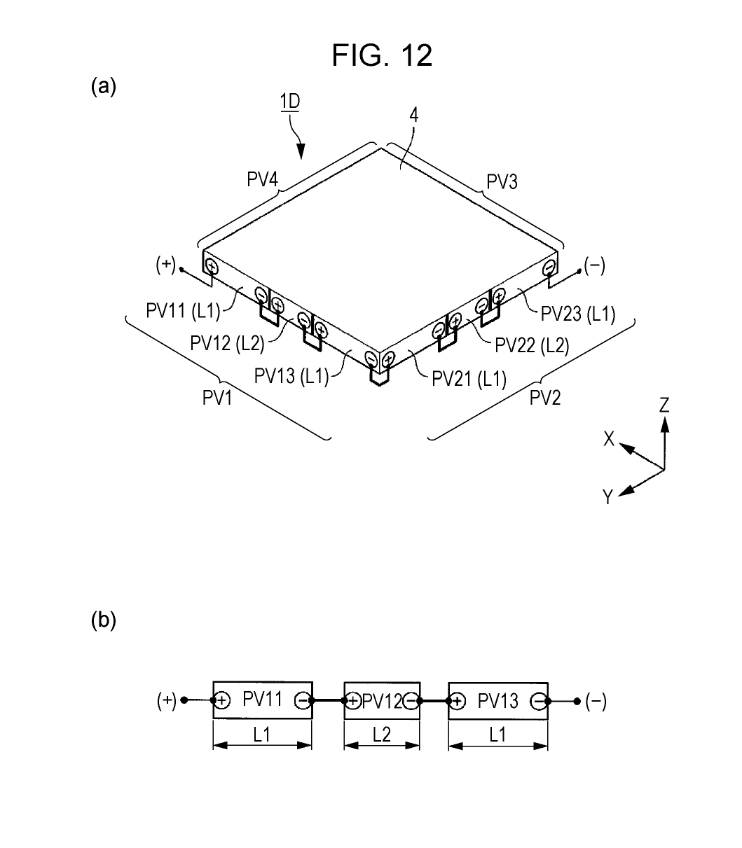

Next, description will be given for another example of an electrical connection relation of solar cells included in a solar cell module 1D as a third embodiment with reference to FIGS. 12(a) and (b). Note that, in the following description, description for parts same as those of the solar cell modules 1, 1A, 1B and 1C shown in the above first and second embodiments are omitted and the same reference numerals are assigned thereto in the figures.

The solar cell module 1D shown in the third embodiment includes the six solar cells PV11 to PV13 and PV21 to PV23 constituting the two solar cell element groups PV1 and PV2 that are arranged on the two adjacent first end surfaces 4c among the four solar cell element groups PV1, PV2, PV3 and PV4 that are arranged on the four first end surfaces 4c of the above light-guiding body 4. That is, these six solar cells PV11 to PV13 and PV21 to PV23 are arranged side by side in three pieces on the two first end surfaces 4c of the light-guiding body 4 to thereby constitute the two solar cell element groups PV1 and PV2.

Note that, in FIG. 12(a), one of electrodes provided on the inner surface (light-receiving surface) side of each of the solar cells PV11 to PV13 and PV21 to PV23 is not able to be illustrated and hence both electrodes (+) and (−) are illustrated on the outer surface side for convenience. Further, in FIG. 12(a), while the above two solar cell element groups PV1 and PV2 of the four solar cell element groups PV1, PV2, PV3 and PV4 are illustrated, the two solar cell element groups PV3 and PV4 on the opposite side thereto are not illustrated but have a structure in contrast to those of the two solar cell element groups PV1 and PV2. That is, the solar cell element group PV3 and the solar cell element group PV4 have the structure corresponding to the solar cell element group PV1 and the solar cell element group PV2, respectively.

FIG. 12(b) is an equivalent circuit of the solar cells PV11 to PV13 constituting the solar cell element group PV1. Note that, the remaining three solar cell element groups PV2 to PV4 basically have the same structure as that of this solar cell element group PV1, and therefore are omitted from the figure to be explained collectively.

In the structure shown in FIG. 12(b), among the three solar cells PV11 to PV13 that are arranged side by side on the first end surface 4c of the light-guiding body 4, lengths L1 of the solar cells PV1 and PV3 that are arranged at both end portions are longer than a length L2 of the solar cell PV2 that is arranged at the center portion (L1>L2). In addition, these three solar cells PV11 to PV13 are mutually serially connected.

Moreover, as shown in FIG. 12(a), the solar cell PV13 constituting the above solar cell element group PV1 and the solar cell PV21 constituting the above solar cell element group PV2 are serially connected.

Here, in the case of having the structure shown in FIG. 12(b) above, when the energy conversion efficiency by the solar cell PV11 is η11, the energy conversion efficiency by the solar cell PV12 is η12, the energy conversion efficiency by the solar cell PV13 is η13, and the energy conversion efficiency by the three solar cells PV11 to PV13 (solar cell element group PV1) is η123, these η11, η12, η13 and η123 are able to be expressed by following formulas (15) to (18).

η11=Voc11×Isc11×FF (15)

η12=Voc12×Isc12×FF (16)

η13=Voc13×Isc13×FF (17)

η123=(Voc11+Voc12+Voc13)×Isc_min_{—}5×FF (18)

Voc11 to Voc13: open circuit voltages of PV11 to PV13
Isc11 to Isc13: short circuit currents of PV11 to PV13
Isc_min_5: minimum short circuit current among Isc11 to Isc13

As described above, the short circuit current when a plurality of solar cells are mutually serially connected is rate-determined by the short circuit current of the solar cell indicating the minimum current value.

Here, the above short circuit current Isc is able to be expressed by a following formula (19) and this formula (19) shows that the above short circuit current Isc becomes large in proportion to a light-receiving area of the solar cell.

$$\begin{matrix}[ Expression 1 ] & \\ {i}_{sc} = qS {\int }_{0}^{∞} F ( λ ) η ( λ ) ext d λ & ( 19 )\end{matrix}$$

F(λ): photon count per unit area and per unit time corresponding to incident light (λ)
η(λ): external collection efficiency
λ: wavelength of incident light [μm]
S: effective area of solar cell
q: elementary charge

In the above three solar cells PV11 to PV13, the lengths L1 of the solar cells PV1 and PV3 that are arranged at both end portions are longer than the length L2 of the solar cell PV2 that is arranged at the center portion described above. Therefore, the solar cells PV1 and PV3 that are arranged at both end portions have a larger light-receiving area than that of the solar cell PV2 that is arranged at the center portion.

On the other hand, according to the graph shown in FIG. 4 above, the light intensity received by each of the solar cells PV11 to PV13 is reduced as being close to both end portions across the center portion of the light-guiding body 4.

Accordingly, when the above three solar cells PV11 to PV13 are mutually serially connected, by changing the length (light-receiving area) of each of the solar cells PV11 to PV13 according to the light intensity received by each of the solar cells PV11 to PV13, it is possible to uniform the short circuit currents Isc11 to Isc13 flowing in these three solar cells PV11 to PV13 (Isc11≈Isc12≈Isc13).

That is, in the structure shown in FIG. 12(b) above, the lengths L1 of the solar cells PV1 and PV3 that are arranged at both end portions are longer than the length L2 of the solar cell PV2 that is arranged at the center portion described above so that each of the short circuit currents Isc11 to Isc13 of the above three solar cells PV11 to PV13 is equal.

Thereby, as to the short circuit current Isc_min_5 when the above three solar cells PV11 to 13 are serially connected, differences between the short circuit currents Isc11 to Isc13 of each of the solar cells PV11 to PV13 are small (averaged), so that a loss is also able to be made much smaller.

Further, the open circuit voltage when the above three solar cells PV11 to PV13 are serially connected is a sum of the above Voc12 to Voc13 as shown in the above formula (18).

As above, in the case of having the structure shown in FIG. 12 above, it is possible to suppress the loss due to connection of the open circuit voltage and the short circuit current described above low, thus making it possible to increase the energy conversion efficiency thereof.

Accordingly, the solar cell module 1D in the third embodiment has such a structure with high energy conversion efficiency to thereby enable the substantial increase in the module output.

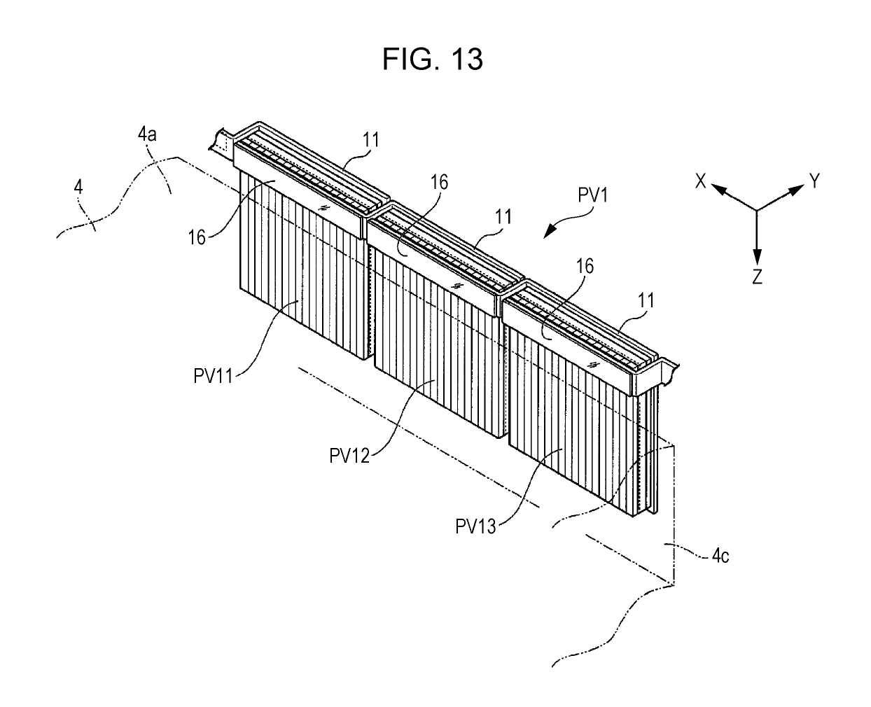

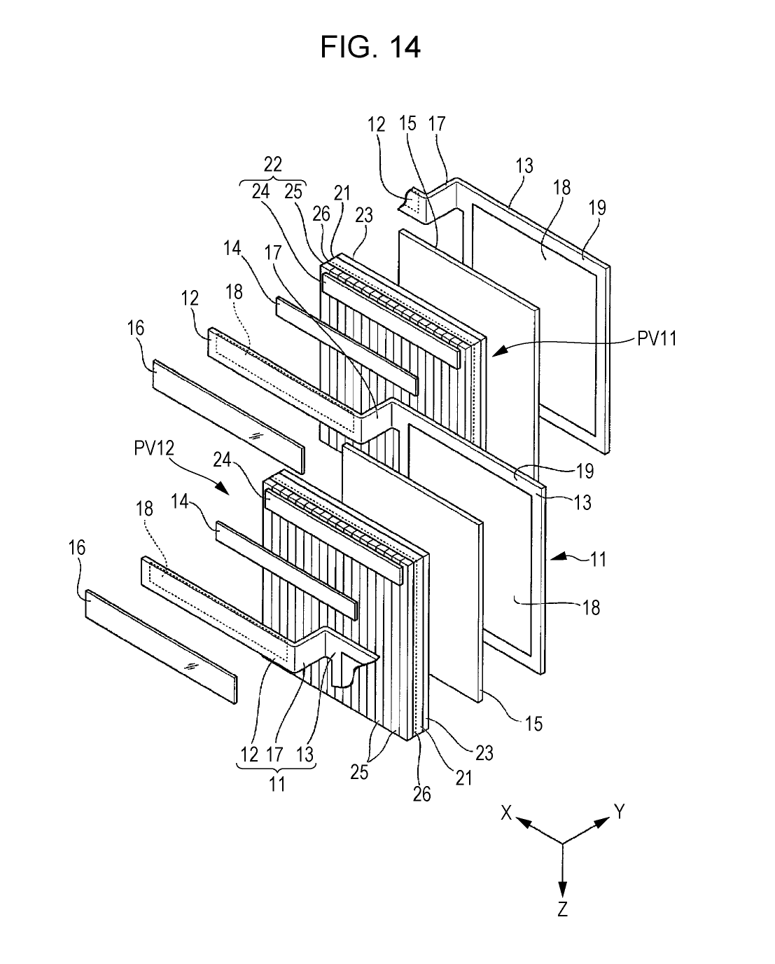

Next, description will be given for a specific structure of solar cells included in the above solar cell module 1D with reference to FIG. 13 and FIG. 14.

Note that, FIG. 13 is a partial perspective view of the solar cell element group PV1 in the third embodiment. FIG. 14 is an exploded perspective view of the solar cell element group PV1 in the third embodiment. Note that, the remaining three solar cell element groups PV2 to PV4 basically have the same structure as that of this solar cell element group PV1, and therefore are omitted from the figures to be explained collectively.

The solar cell element group PV1 includes a plurality of flexible substrates (Flexible printed circuits; FPC) 11 on which the plurality of solar cells PV11 to PV13 which are arranged to be adjacent to each other along the first end surface 4c of the light-guiding body 4 are serially connected to each other.

Each of the solar cells PV1 to PV3 includes a semiconductor substrate 21, finger electrodes 25 and a bus bar electrode 24 which are formed on one surface side of the semiconductor substrate 21, and a back-side electrode 23 which is formed on the other surface side of the semiconductor substrate 21.

The semiconductor substrate 21 is a P-type semiconductor substrate, for example, having a rectangular shape. As the semiconductor substrate 21, publicly known various semiconductor substrates such as a monocrystalline silicon substrate, a polycrystalline silicon substrate and a gallium-arsenide substrate are usable. An N-type impurity layer 26 is formed on one surface side of the semiconductor substrate 21, and PN junction is formed on an interface between the N-type impurity layer 26 and a P-type area of the semiconductor substrate 21.

The plurality of finger electrodes 25 are formed to be adjacent to each other along one side of the semiconductor substrate 21 on a front surface of the N-type impurity layer 26. The bus bar electrode 24 by which these plurality of finger electrodes 25 are connected is formed on one end side of the plurality of finger electrodes 25. The bus bar electrode 24 is formed in a stripe manner along the above one side of the semiconductor substrate 21 so as to extend across the plurality of finger electrodes 25. A first current-collecting electrode 22 is formed by the plurality of finger electrodes 25 and the bus bar electrode 24. The back-side electrode 23 as a second current-collecting electrode is formed on the other surface side of the semiconductor substrate 21 so as to almost cover the entire other surface of the semiconductor substrate 21.

The flexible substrates 11 are flexible wiring substrates which are formed by laminating a conductive layer 18 on an insulating film 19. Used as the flexible substrate 11 is, for example, one in which upper and lower surfaces of the conductive layer 18 such as copper foil are covered with the insulating film 19 such as polyimide and a part of the insulating film 19, which is connected to the solar cells PV11 to PV13, is removed to expose the conductive layer 18.

The flexible substrate 11 includes a first electrode unit 12 that is connected to the bus bar electrode 24, a second electrode unit 13 that is connected to the back-side electrode 23, and a connection unit 17 by which the first electrode unit 12 and the second electrode unit 13 are connected. In the flexible substrate 11, the first electrode unit 12 at one end side thereof is connected to the bus bar electrode 24 of one solar cell, and the second electrode unit 13 at the other end side thereof and the connection unit 17 are bent along an end surface of the one solar cell to be connected to the back-side electrodes 23 of the next solar cell. The connection unit 17 is bent at a substantially right angle along an end surface of the solar cell 5 so that a large gap is not generated between solar cells.

The flexible substrate 11 is connected to the bus bar electrode 24 and the back-side electrode 23 by using conductive films 14 and 15. The conductive films 14 and 15 are obtained by dispersing fine conductive particles into the inside of a resin to mold in a film shape having thickness from about 10 μm to 100 μm. As the conductive films 14 and 15, an anisotropic conductive film (ACF) and the like are usable, and not only one having conductive property only in a thickness direction like the anisotropic conductive film but also one having conductive property in both the thickness direction and a direction which is perpendicular thereto are usable.

A reflection layer 16 that reflects light incident from the first end surface 4c of the light-guiding body 4 is provided on a surface opposing to the first end surface 4c of the light-guiding body 4 in the flexible substrate 11. By providing the reflection layer 16, absorption of the light by the flexible substrate 11 is suppressed, thus making it possible to use the light from the light-guiding body 4 for power generation effectively.

Note that, the present invention is not necessarily limited to the above third embodiment, and may be variously modified without departing from the gist of the present invention.

For example, the solar cell module 1D shown in the above third embodiment has been explained by taking a case where three solar cells are serially connected, and further these three solar cells have different lengths as an example. However, the number of these solar cells N is able to be changed according to a design of the above solar cell module 1D.

That is, the solar cell module 1D shown as the above third embodiment merely may have a structure that the N solar cells are arranged side by side along one side of the light-guiding body 4, and light-receiving areas of the solar cells are increased sequentially as being close to both end portions from the center portion in an arrangement direction of the N solar cells that are mutually serially connected so that each of the short circuit currents of the N solar cells in the case of making the exterior light incident on the entire light incidence surface uniformly is equal.

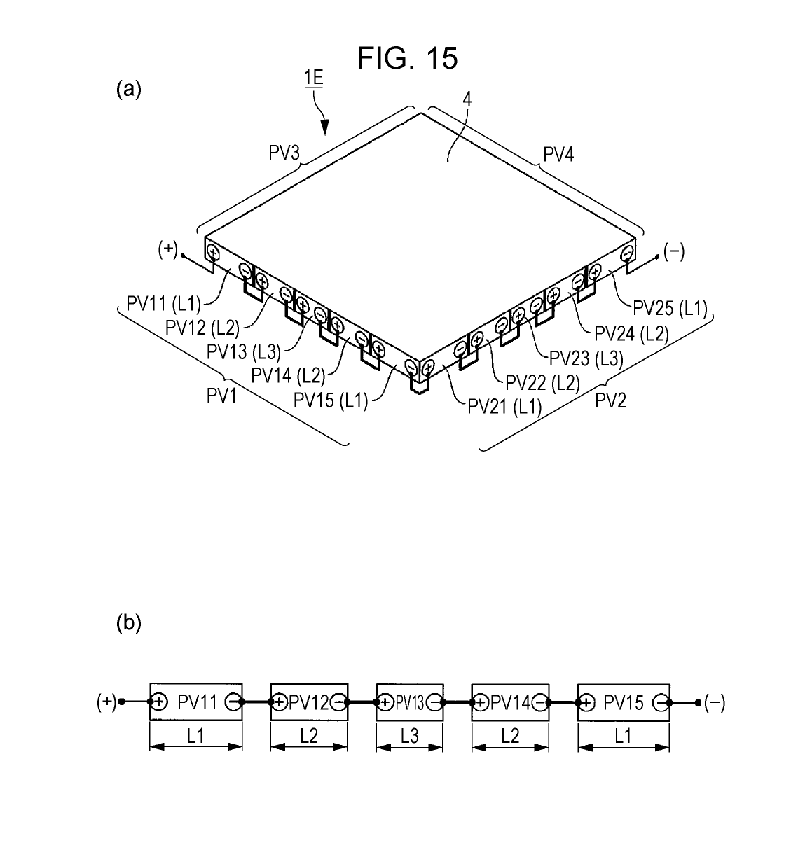

Accordingly, a solar cell module 1E having a structure as shown in FIG. 15, for example, is also allowed.

Specifically, FIG. 15(a) is a schematic wiring view of the solar cells PV11 to PV15 and PV21 to PV25 constituting the two solar cell element groups PV1 and PV2 that are arranged on the two adjacent first end surfaces 4c in the above two solar cell element groups PV1 and PV2.

Note that, in FIG. 15(a), one of electrodes provided on the inner surface (light-receiving surface) side of each of the solar cells PV11 to PV15 and PV21 to PV25 is not able to be illustrated and hence both electrodes (+) and (−) are illustrated on the outer surface side for convenience. Further, in FIG. 15(a), while the two solar cell element groups PV1 and PV2 of the four solar cell element groups PV1, PV2, PV3 and PV4 are illustrated, the two solar cell element groups PV3 and PV4 on the opposite side thereto are not illustrated but have a structure in contrast to those of the two solar cell element groups PV1 and PV2. That is, the solar cell element group PV3 and the solar cell element group PV4 have the structure corresponding to the solar cell element group PV1 and solar cell element group PV2, respectively.

FIG. 15(b) is an equivalent circuit of the solar cells PV11 to PV15 constituting the solar cell element group PV1. Note that, the remaining three solar cell element groups PV2 to PV4 basically have the same structure as that of this solar cell element group PV1, and therefore are omitted from the figure to be explained collectively.

In the structure shown in FIG. 15(b), among the five solar cells PV11 to PV15 that are arranged side by side on the first end surface 4c of the light-guiding body 4, lengths L2 of the solar cells PV2 and PV4 that are arranged on both sides of the solar cell PV3 are longer than a length L3 of the solar cell PV3 that is arranged at the center portion (L2>L3). Further, lengths L1 of the solar cells PV1 and PV5 that are arranged at both end portions are longer than the lengths L2 of these solar cells PV2 and PV4 (L1>L2). In addition, these five solar cells PV11 to PV15 are mutually serially connected.

Moreover, each of the lengths L1, L2 and L3 of each of the solar cells PV11 to PV15 is adjusted so that each short circuit current of the above five solar cells PV11 to PV15 is equal.

Moreover, as shown in FIG. 15(a), the solar cell PV15 constituting the above solar cell element group PV1 and the solar cell PV21 constituting the above solar cell element group PV2 are serially connected.

Accordingly, when the above five solar cells PV11 to 13 are serially connected, similarly to the case where the above three solar cells PV11 to 13 are serially connected, it is possible to suppress the loss due to connection of the open circuit voltage and the short circuit current described above low, and it is possible to increase the energy conversion efficiency thereof.

Accordingly, the above solar cell module 1E has such a structure with high energy conversion efficiency to thereby enable the substantial increase in the module output.

### Fourth Embodiment

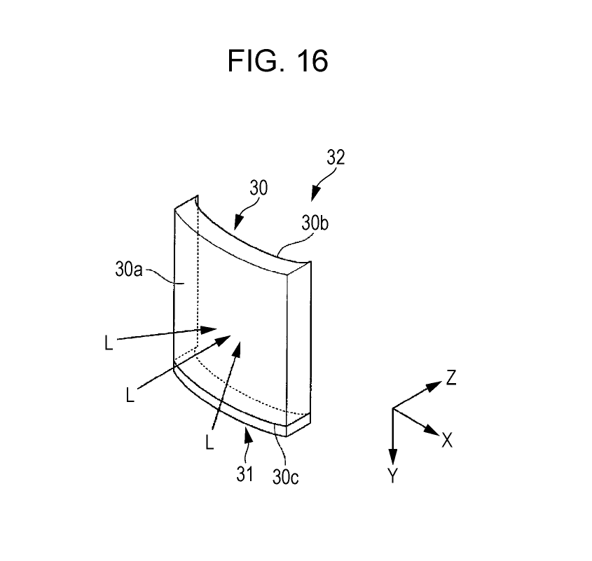

Next, description will be given for a solar cell module 32 shown in FIG. 16 as a fourth embodiment.

Note that, FIG. 16 is a schematic view of the solar cell module 32 shown as the fourth embodiment.

In the solar cell module 32, a light-guiding body 30 and a solar cell element 31 have different shapes and arrangement. Thus, the shapes and the arrangement of the light-guiding body 30 and the solar cell element group 31 will be described and detailed description of other components is omitted.

In the solar cell module 32, the light-guiding body 30 is configured as a curved plate-shaped member, and the solar cell element group 31 is configured so as to receive light emitted from a curved first end surface 30c of the light-guiding body 30, which serves as a light-emitting surface. The light-guiding body 30 has a shape that, for example, a plate-shaped member having fixed thickness is curved around an axis in parallel to a Y axis. A first main surface 30a which is curved outward in a convex shape among the first main surface 30a and a second main surface 30b of the light-guiding body 30 is a light incidence surface on which exterior light (for example, sunlight) is incident.

In the solar cell module 32, the light incidence surface 30a of the light-guiding body 30 is a curved surface. Therefore, even when an incidence angle of light L changes along a curving direction of the light-guiding body 30 depending on a time zone such as daytime or evening, a power generation amount does not change largely. When power is generated by solar cells, ordinarily, a tracking apparatus is provided to control angles of the solar cells in two axial directions so that the light-receiving surfaces of the solar cells face the light incidence direction of the light, however, when the light incidence surface 30a of the light-guiding body 30 has the curved shape so as to face various directions like the present embodiment, such a tracking apparatus does not need to be provided. Even if the tracking apparatus is provided, it is only necessary to control an angle in a direction perpendicular to the curving direction, so that it is possible to simplify a structure of the tracking apparatus compared to the case where the angle control is performed in two axial directions. The light-guiding body 30 has the shape curved in one direction in the case of the present embodiment, but the shape of the light-guiding body 30 is not limited thereto. For example, a domical shape such as a hemispherical shape or a bell shape is also possible. In this case, the tracking apparatus is not necessary.

Since the solar cell module 32 has the light-guiding body 30 that is curved, the light-guiding body 30 is able to be installed on a wall surface or roof of a building, which is formed in a curve shape. The light-guiding body 30 has the shape curved in one direction in the case of the present embodiment, but the shape of the light-guiding body 30 is not limited to such a simple shape. For example, it is possible to design in a free shape such as an imbricate shape or a waved shape. Further, the light-guiding body 30 may have not only the curved shape but a bent shape that is bent with ridge lines depending on an installation place thereof. These curved surface and bent surface merely need to be provided at least a part of the light incidence surface, thereby the effect described above can be achieved.

### [Photovoltaic Apparatus]

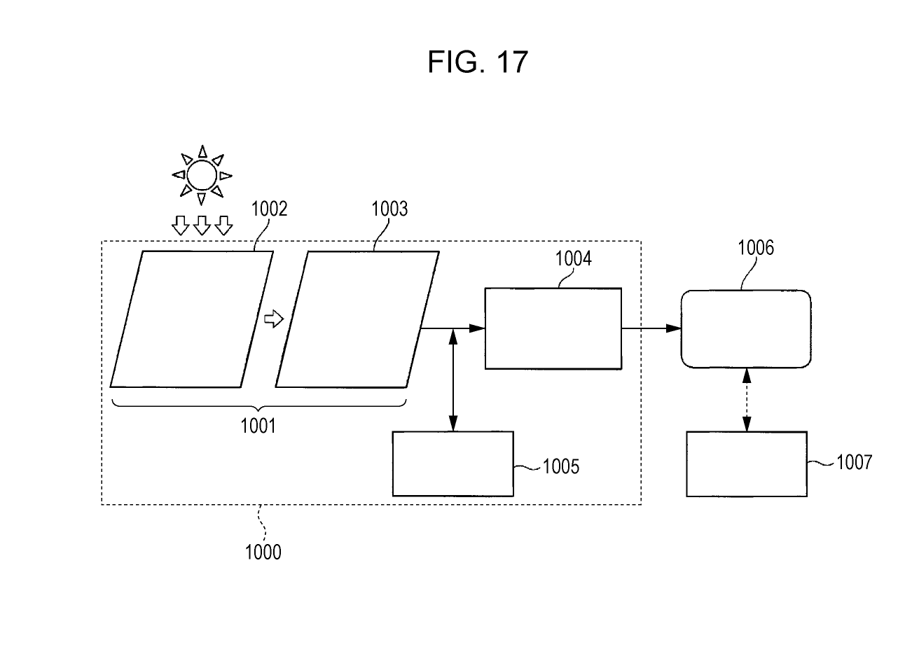

FIG. 17 is a schematic structural view of a photovoltaic apparatus 1000.

The photovoltaic apparatus 1000 includes a solar cell module 1001 which converts energy of sunlight into electric power, an inverter (direct-current/alternating-current converter) 1004 which converts direct-current power output from the solar cell module 1001 into alternating-current power, and a storage battery 1005 in which the direct-current power output from the solar cell module 1001 is stored.

The solar cell module 1001 includes a light-guiding body 1002 which condenses sunlight, and a solar cell element 1003 which performs power generation by the sunlight condensed by the light-guiding body 1002. As the solar cell module 1001, for example, the solar cell module described in the first embodiment to the fourth embodiment or a modified form thereof is used.

The photovoltaic apparatus 1000 supplies electric power to external electronic equipment 1006. Electric power is supplied from an auxiliary power source 1007 as necessary to the electronic equipment 1006.

The photovoltaic apparatus 1000 includes the solar cell modules according to the present invention described above, and hence serves as the photovoltaic apparatus having high power generation efficiency.

### INDUSTRIAL APPLICABILITY

The present invention is able to be used for a solar cell module and a photovoltaic apparatus.

### REFERENCE SIGNS LIST

1, 1A, 1B, 1C, 1D solar cell module
4 light-guiding body
4a first main surface (light incidence surface)
4c first end surface (light-emitting surface)
PV1 to PV4 solar cell element group
PV11 to PV18, PV21 to PV24, PV31 to PV34, PV41 to PV44 solar cell
PV101 to PV107, PV201 parallel-connection block
11 flexible substrate
14, 15 conductive film
16 reflection layer
18 conductive layer
19 insulating film
21 semiconductor substrate
22 first current-collecting electrode
23 back-side electrode (second current-collecting electrode)
30 light-guiding body
30a first main surface (light incidence surface)
30c first end surface (light-emitting surface)
31 solar cell element
32 solar cell module
33 light-guiding body
33a first main surface (light incidence surface)
33c first end surface (light-emitting surface)
34 solar cell element
35 solar cell module
1000 photovoltaic apparatus

1. A solar cell module, comprising:
a light-guiding body which has a light incidence surface and a light-emitting surface having an area smaller than that of the light incidence surface and converts exterior light incident from the light incidence surface into fluorescent light by a phosphor to emit from the light-emitting surface; and
N (N is an integer of 4 or more) solar cells of a same type which receive the fluorescent light emitted from the light-emitting surface of the light-guiding body, wherein
the N solar cells are connected in parallel in a plurality of pieces to thereby form L (L is an integer of 2 or more) parallel-connection blocks each of which has the plurality of solar cells mutually connected in parallel, and
the L parallel-connection blocks are mutually serially connected.

2. The solar cell module according to claim 1, wherein
when each short circuit current of the N solar cells in the case of making the exterior light incident on the entire light incidence surface uniformly is Iⱼ (j is an integer from 1 to N),
a sum of short circuit currents of the plurality of solar cells included in each parallel-connection block of the L parallel-connection blocks is ITᵢ (i is an integer from 1 to L),
a difference, among arbitrary two of the parallel-connection blocks selected from the L parallel-connection blocks, between the ITᵢs of the two parallel-connection blocks that have a greatest difference between the ITᵢs is ID₁, and
a difference, among arbitrary two of the solar cells selected from the N solar cells, between the Iⱼs of the two solar cells that have a greatest difference between the Iⱼs is ID₂,
the ID₁ and the ID₂ satisfy a relational expression of ID₁<ID₂.

3. The solar cell module according to claim 1, wherein
the light-guiding body is a plate-shaped body having one or more side,
the N solar cells are arranged side by side along one side of the light-guiding body, and
a solar cell that is arranged at one end portion in an arrangement direction of the N solar cells and a solar cell that is arranged at the other end portion in the arrangement direction of the N solar cells are included in the parallel-connection blocks which are different from each other.

4. A solar cell module, comprising:
a light-guiding body which has a light incidence surface and a light-emitting surface having an area smaller than that of the light incidence surface and converts exterior light incident from the light incidence surface into fluorescent light by a phosphor to emit from the light-emitting surface; and
N (N is an integer of 3 or more) solar cells of a same type which receive the fluorescent light emitted from the light-emitting surface of the light-guiding body, wherein
M (M is an integer larger than 1 and smaller than N) solar cells of the N solar cells are connected in parallel in a plurality of pieces to thereby form L (L is an integer of 1 or more) parallel-connection blocks each of which has a plurality of solar cells mutually connected in parallel and (N-M) solar cell which is not included in the L parallel-connection blocks, and
the L parallel-connection blocks and the (N-M) solar cell are mutually serially connected.

5. The solar cell module according to claim 4, wherein
when each short circuit current of the N solar cells in the case of making the exterior light incident on the entire light incidence surface uniformly is Iⱼ (j is an integer from 1 to N), a solar cell having a minimum Iⱼ is included in any of the L parallel-connection blocks.

6. The solar cell module according to claim 4, wherein
when each short circuit current of the N solar cells in the case of making the exterior light incident on the entire light incidence surface uniformly is Iⱼ (j is an integer from 1 to N),
a sum of short circuit currents of the plurality of solar cells included in each parallel-connection block of the L parallel-connection blocks is ITᵢ (i is an integer from 1 to L),
a difference, among arbitrary two of the parallel-connection blocks selected from the L parallel-connection blocks, between the ITᵢs of the two parallel-connection blocks that have a greatest difference between the ITᵢs is ID₁,
a difference, among arbitrary two of the solar cells selected from the N solar cells, between the Iⱼs of the two solar cells that have a greatest difference between the Iⱼs is ID₂, and
a difference, among arbitrary one of the parallel-connection block selected from the L parallel-connection blocks and arbitrary one of the solar cell selected from the (N-M) solar cell, between the ITᵢ and the Iⱼ of the one parallel-connection block and the one solar cell that have a greatest difference between the ITᵢ and the Iⱼ is ID₃,
the ID₁, the ID₂ and the ID₃ satisfy relational expressions of ID₁<ID₂ and ID₃<ID₂.

7. The solar cell module according to claim 4, wherein
the light-guiding body is a plate-shaped body having one or more side,
the N solar cells are arranged side by side along one side of the light-guiding body, and
at least one of a solar cell that is arranged at one end portion in an arrangement direction of the N solar cells and a solar cell that is arranged at the other end portion in the arrangement direction of the N solar cells is included in any of the L parallel-connection blocks.

8. A solar cell module, comprising:
a light-guiding body which has a light incidence surface and a light-emitting surface having an area smaller than that of the light incidence surface and converts exterior light incident from the light incidence surface into fluorescent light by a phosphor to emit from the light-emitting surface; and
N (N is an integer of 3 or more) solar cells which receive the fluorescent light emitted from the light-emitting surface of the light-guiding body, wherein
the light-guiding body is a plate-shaped body having one or more side,
the N solar cells are arranged side by side along one side of the light-guiding body and constituted by being mutually serially connected, and
light-receiving areas of the solar cells are increased sequentially as being close to both end portions from a center portion in an arrangement direction of the N solar cells.

9. The solar cell module according to claim 8, wherein
the light-receiving areas of the solar cells are increased sequentially as being close to both end portions from the center portion in the arrangement direction of the N solar cells such that each short circuit current of the N solar cells in the case of making the exterior light incident on the entire light incidence surface uniformly is equal.

10. The solar cell module according to claim 8, wherein
the light-receiving areas of the N solar cells vary in accordance with a length of each of the solar cells.

11. A photovoltaic apparatus provided with the solar cell module according to claim 1.
